(19) United States
(12) Patent Application Publication
(10) Pub. No.: US 2026/0311788 A1
(43) Pub. Date: Oct. 8, 2026

(54) MEMORY SYSTEM, MEMORY CONTROLLER, AND METHOD OF OPERATING MEMORY CONTROLLER WITH TRAINING CIRCUIT

(71) Applicant: Samsung Electronics Co., Ltd., Suwon-si (KR)

(72) Inventors: Kwanghoon KIM, Suwon-si (KR); Seonghyeog CHOI, Suwon-si (KR); Daewook KIM, Suwon-si (KR); Changkyu SEOL, Suwon-si (KR)

(73) Assignee: Samsung Electronics Co., Ltd., Suwon-si (KR)

(21) Appl. No.: 19/569,745

(22) Filed: Mar. 17, 2026

(30) Foreign Application Priority Data
Apr. 4, 2025 (KR) 10-2025-0044275

(51) Int. Cl. G11C 21/00; G11C 7/22

(52) U.S. Cl. CPC G11C 21/005; G11C 7/222; G11C 2207/2254

(57) ABSTRACT

According to some example embodiments, a memory system includes a memory device, and a memory controller configured to control the memory device, the memory controller including a training circuit, the training circuit configured to generate a plurality of reference pattern data, the plurality of reference pattern data including a plurality of pieces of reference pattern data, the plurality of pieces of reference pattern data generated by cyclically shifting basic pattern data in units of unit intervals, generate a comparison result by simultaneously comparing the plurality of reference pattern data to sampling data, and calculate a center of a window of a data signal based on the comparison result.

### CROSS-REFERENCE TO RELATED APPLICATION

This application claims priority under 35 U.S.C. § 119 to Korean Patent Application No. 10-2025-0044275, filed on Apr. 4, 2025, in the Korean Intellectual Property Office, the disclosure of which is incorporated by reference herein in its entirety.

### BACKGROUND

The inventive concepts relate to a semiconductor memory, and for example, to a memory system, a memory controller, and/or a method of operating the memory controller.

Semiconductor memories are classified into volatile memory devices, such as static random access memory (RAM) (SRAM) and dynamic RAM (DRAM), and non-volatile memory devices, which maintain stored data even when power supply thereto is cut off, such as phase change RAM (PRAM), magnetic RAM (MRAM), resistive RAM (RRAM), and ferro-electric RAM (FRAM).

Memory controllers and memory devices communicate with each other by using data signals. To increase the reliability of data transmission using the data signals between the memory controllers and the memory devices, training may be performed. The training may include transmission of data in parallel by using the data signals and/or alignment of arrival timings.

A memory controller may perform training on a memory device after power-up to compensate for timing for at least one of a data signal (or DQ signal) transmitted and/or sent through a data line and a data strobe signal (or DQS signal) transmitted and/or sent through a data strobe line, to meet optimum alignment conditions, and control memory operations.

### SUMMARY

The inventive concepts provide memory systems having improved training speed, memory controllers, and/or methods of operating memory controllers.

According to some example embodiments, a memory system includes a memory device, and a memory controller configured to control the memory device, the memory controller including a training circuit, the training circuit configured to generate a plurality of reference pattern data, the plurality of reference pattern data including a plurality of pieces of reference pattern data, the plurality of pieces of reference pattern data generated by cyclically shifting basic pattern data in units of unit intervals; generate a comparison result by simultaneously comparing the plurality of reference pattern data to sampling data; and calculate a center of a window of a data signal based on the comparison result.

According to some example embodiments, a method of operating a memory controller includes generating a plurality of reference pattern data by cyclically shifting basic pattern data by units of unit intervals, generating a comparison result by simultaneously comparing sampling data to the plurality of reference pattern data by performing, repeatedly, a sub-training operation, and calculating a center of a window of a data signal based on the comparison result.

According to some example embodiments, a memory controller is configured to control a memory device, the memory controller including a training circuit, the training circuit including a pattern generator configured to generate a plurality of reference pattern data by cyclically shifting basic pattern data by units of unit intervals, and a comparator cluster including a plurality of comparators, each of the plurality of comparators configured to receive sampling data, receive corresponding reference pattern data from the pattern generator, compare the sampling data to the corresponding reference pattern data, and generate a comparison result.

### BRIEF DESCRIPTION OF THE DRAWINGS

Some example embodiments of the inventive concepts will be more clearly understood from the following detailed description taken in conjunction with the accompanying drawings in which:

FIG. 1 is a block diagram illustrating a memory system according to some example embodiments;

FIG. 2 is a flowchart of an operation of a memory system in FIG. 1, according to some example embodiments;

FIG. 3 is a more detailed block diagram of a training circuit in FIG. 1 according some example embodiments;

FIG. 4 is a flowchart of an operation of a memory controller in FIG. 1, according to some example embodiments;

FIG. 5 is a diagram of an example of a plurality of reference pattern data, according to some example embodiments;

FIG. 6 is a diagram of an example of an initial delay amount of a plurality of reference pattern data, according to some example embodiments;

FIG. 7 is a more detailed block diagram of a comparator cluster in FIG. 1 according to some example embodiments;

FIG. 8 is a flowchart of an operation of the memory system in FIG. 1, according to some example embodiments;

FIG. 9A, FIG. 9B, and FIG. 9C are diagrams for describing operations of the memory controller in FIG. 1, according to some example embodiments;

FIG. 10 is a diagram of examples of reference pattern data and sampling data, according to some example embodiments;

FIG. 11 is a diagram of a comparison result according to some example embodiments;

FIG. 12 is a flowchart of an example of an operation of the memory system in FIG. 1, according to some example embodiments;

FIG. 13 is a flowchart of an example of an operation of the memory controller in FIG. 1, according to some example embodiments;

FIG. 14 is a more detailed block diagram of the training circuit in FIG. 1 according to some example embodiments;

FIG. 15 is a more detailed block diagram of the training circuit in FIG. 1 according to some example embodiments;

FIG. 16A, FIG. 16B, FIG. 16C, FIG. 16D, FIG. 16E, and FIG. 16F are graphs of effects of a memory system, according to some example embodiments;

FIG. 17 is a block diagram illustrating a memory system according to some example embodiments; and

FIG. 18 is a block diagram of a storage system according to some example embodiments.

### DETAILED DESCRIPTION

Hereinafter, some example embodiments of the inventive concepts are described clearly and in detail so that one of ordinary skill in the art easily implements the inventive concepts.

In some example embodiments, the term ‘training’ as used in the inventive concepts may be referred to as an operation of searching and adjusting the center of a window of a data signal DQ. In some example embodiments, the “left edge (LE)” may be referred to as a closed portion of the left side (or earlier timewise) of a unit interval (UI) constituting the window of the data signal DQ. The “right edge (RE)” may be referred to as a closed portion of the right side (or, later timewise) of the UI of the data signal DQ. In some example embodiments, the expression of the UI may be used in parallel with the term of a window of the data signal DQ.

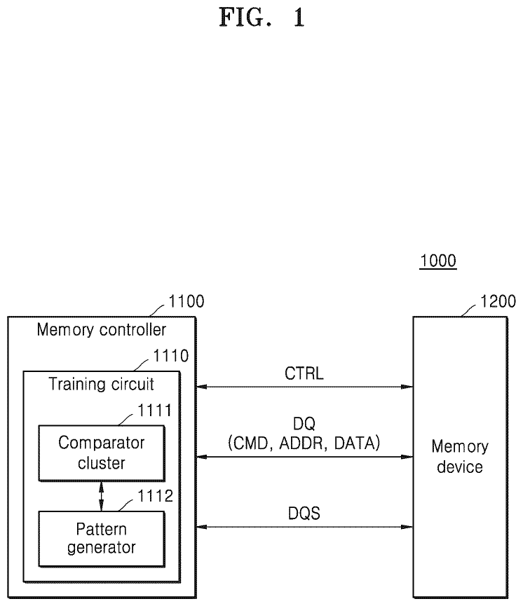

FIG. 1 is a block diagram illustrating a memory system 1000 according to some example embodiments.

Referring to FIG. 1, the memory system 1000 may include a memory controller 1100 and a memory device 1200. In some example embodiments, the memory system 1000 may include a mass storage medium used in a computing device, such as a storage device, a solid state drive (SSD), and/or a memory card. In some example embodiments, the memory system 1000 may basically include a mobile system, such as a mobile phone, a smartphone, a tablet personal computer (PC), a wearable device, a health care device, and/or an Internet of Things (IoT) device. However, example embodiments of the memory system 1000 are not necessarily limited thereto, and, according to some example embodiments, the memory system 1000 may also include a PC, a laptop computer, a server, a media player, and/or an automotive device such as a navigation device.

The memory controller 1100 may be configured to control the memory device 1200 according to a request or control of an external device (for example, a host, a central processing unit (CPU), an application processor (AP), etc.). For example, to control the memory device 1200, the memory controller 1100 may exchange various signals by using a control signal CTRL, the data signal DQ (or a plurality of data signals), and a data strobe signal DQS.

For example, the control signal CTRL, the data strobe signal DQS, and the data signal DQ may be provided to the memory device 1200 via different signal lines and/or different signal pins. The control signal CTRL and the data strobe signal DQS may include signals for distinguishing between signals provided to the memory device 1200 via the data signal DQ (for example, command CMD, address ADDR, or data DATA). For example, the data signal DQ may be referred to as a signal transceived via a data signal pin DQ pin or a data line, and the data strobe signal DQS may be referred to as a signal transceived via a data strobe pin (DQS pin) and/or the data strobe line.

The memory device 1200 may, in response to various signals from the memory controller 1100, store the data DATA received from the memory controller 1100 or transmit and/or send the stored data DATA to the memory controller 1100. For example, the memory device 1200 may, based on the control signal CTRL, differentiate whether a signal provided via the data signal DQ is the command CMD, the address ADDR, or the data DATA. In some example embodiments, various signals, such as a command latch enable signal CLE, an address latch enable signal ALE, a read enable signal RE/, and/or a write enable signal WE/, may be provided to the memory device 1200 via the control signal CTRL.

The memory device 1200 may, based on the data strobe signal DQS, be configured to identify (or capture) the data DATA provided via the data signal DQ. The memory device 1200 may store the identified data DATA, based on the received command CMD and address ADDR.

For example, the memory device 1200 may include a NAND flash memory. However, example embodiments of inventive concepts are not limited thereto, and in some example embodiments the memory device 1200 may include at least one of various memory devices, such as static RAM (SRAM), dynamic RAM (DRAM), synchronous DRAM (SDRAM), read only memory (ROM), programmable ROM (PROM), electrically programmable ROM (EPROM), electrically erasable and programmable ROM (EEPROM), a solid-state flash memory device, phase-change RAM (PRAM), magnetic RAM (MRAM), resistive RAM (RRAM), and/or ferro-electric RAM (FRAM).

The memory controller 1100 may be configured to control the memory device 1200. For example, the memory controller 1100 may control the memory device 1200 to perform write, read, and/or erase operations. In some example embodiments, the memory controller 1100 may perform training with the memory device 1200.

The memory controller 1100 may perform the training with the memory device 1200 in particular situations, such as a boot-up or the initialization of the memory system 1000. For example, the training may be performed after power is supplied to the memory system 1000 or after the memory system 1000 is restored from the sleep mode. The training may be performed before the memory controller 1100 generally controls the memory device 1200 (for example, control the memory device 1200 to perform write, read, and/or erase operations).

By using the training, the memory controller 1100 may increase the reliability of data exchange with the memory device 1200. For example, the memory controller 1100 may detect a center of a window of the data signal DQ by writing or reading a training pattern to or from the memory device 1200 under various conditions. The memory controller 1100 may adjust a delay code or a delay amount of a delay circuit to align the detected center of the window of the plurality of data signals DQ.

In some example embodiments, the memory controller 1100 may include a training circuit 1110. In some example embodiments, the training circuit 1110 may include a hardware block including an analog circuit and/or a digital circuit. The training circuit 1110 may include a software block including a plurality of instructions to be executed by the memory controller 1100.

The training circuit 1110 may perform the training with the memory device 1200. The training circuit 1110 may store information that is advantageous for the training, and/or information obtained by the training (for example, pattern data, a final delay amount, or the like), in a memory and/or a register. The training circuit 1110 may perform the training with the memory device 1200 by using the memory and/or the register.

The memory controller 1100 may calculate the difference between the data signal DQ and the data strobe signal DQS by using a comparator while sequentially increasing the delay code. As the timing difference between the data signal DQ and the data strobe signal DQS increases, the training execution time may increase. To improve the performance and reliability of the memory system 1000, it may be advantageous to secure a valid window of the data signal DQ.

The training circuit 1110 according to some example embodiments may perform parallel training operations. The parallel training operation may be referred to as a training step performed by simultaneously comparing a plurality of pieces of reference pattern data to sampling data, based on the plurality of reference pattern data (or reference pattern data) in which the basic pattern data has been cyclically shifted in section units.

In some example embodiments, the training circuit 1110 may generate the plurality of reference pattern data. The training circuit 1110 may simultaneously compare the plurality of reference pattern data to the sampling data, and generate a comparison result. The training circuit 1110 may calculate the center of the window of the data signal DQ based on the comparison result.

For example, the training circuit 1110 may detect the left edge and the right edge of the window of the data signal DQ based on the comparison result. The training circuit 1110 may determine the center of the window of the data signal DQ based on the left edge and the right edge of the window.

In some example embodiments, the training circuit 1110 may include a comparator cluster 1111 and a pattern generator 1112. The pattern generator 1112 may generate the plurality of reference pattern data based on the basic pattern data. For example, the reference pattern data may include comparison pattern data. The reference pattern data may be used to compare to the sampling data received by the comparator. The pattern generator 1112 may provide the plurality of reference pattern data to the comparator cluster 1111.

The comparator cluster 1111 may include a plurality of comparators. The comparator cluster 1111 may receive the plurality of reference pattern data and the sampling data. The comparator cluster 1111 may simultaneously perform a plurality of comparison operations by using the plurality of comparators. The comparator cluster 1111 may simultaneously compare the sampling data to the plurality of reference pattern data. The comparator cluster 1111 may generate the comparison result.

As described above, the training circuit 1110 according to some example embodiments may generate the plurality of reference pattern data by cyclically shifting the basic pattern data in unit interval (UI) units. The training circuit 1110 may simultaneously compare the sampling data to the plurality of reference pattern data by using the plurality of comparators. The training circuit 1110 may improve the training speed by using a parallel structure. Operations of the memory controller 1100 according to some example embodiments of the inventive concepts are described in more detail with reference to the following drawings.

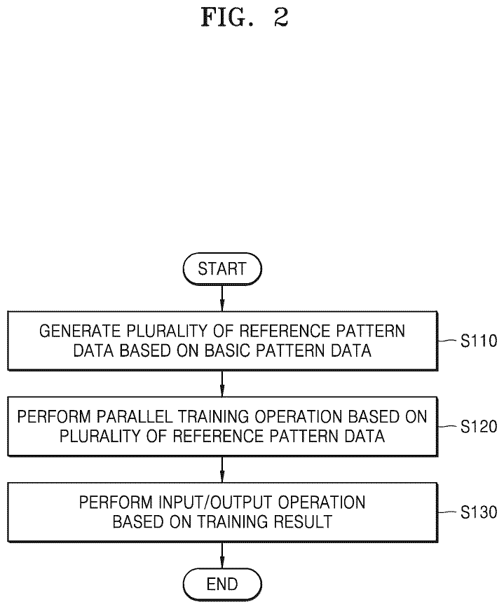

FIG. 2 is a flowchart of an operation of the memory system 1000 of FIG. 1, according to some example embodiments.

Referring to FIGS. 1 and 2, the memory system 1000 may perform a training operation. In operation S110, the memory system 1000 may generate the plurality of reference pattern data based on the basic pattern data. For example, the pattern generator 1112 may generate the plurality of reference pattern data by cyclically shifting the basic pattern data in UI units. A more detailed description of the plurality of reference pattern data is given with reference to FIG. 5.

In operation S120, the memory system 1000 may perform the parallel training operation based on the plurality of reference pattern data. For example, the parallel training operation may be referred to as a training step performed by simultaneously comparing the plurality of reference pattern data to the sampling data. The training circuit 1110 may compare in parallel the sampling data to the plurality of reference pattern data by using the plurality of comparators.

In operation S130, the memory system 1000 may perform input/output operations based on a training result. For example, the memory system 1000 may adjust the delay amount of the data signal DQ based on the training result. The memory system 1000 may compensate for the timing of the data signal DQ. The memory system 1000 may perform the input/output operation with reference to the final delay amount for the data signal DQ or the data strobe signal DQS. Accordingly, a memory system with improved reliability may be provided by reducing a skew between signals generated in a high frequency operation.

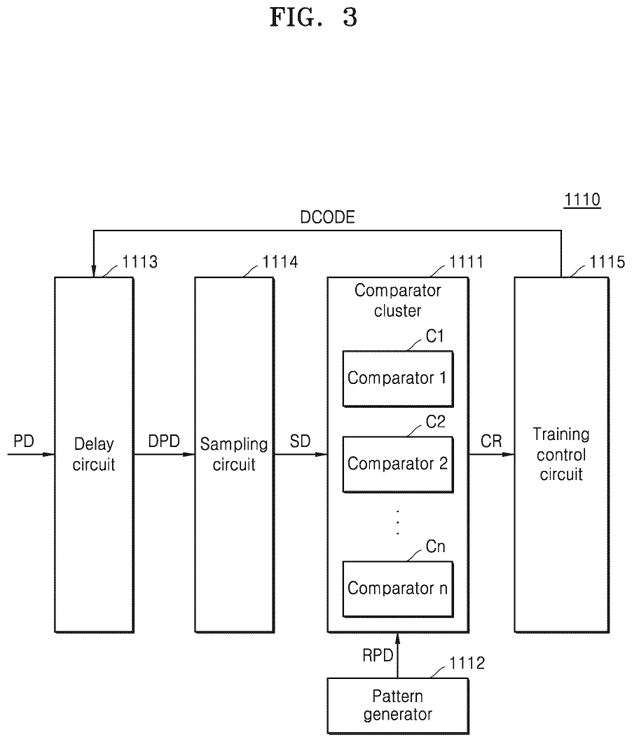

FIG. 3 is a more detailed block diagram of the training circuit 1110 in FIG. 1 according to some example embodiments.

Referring to FIGS. 1 and 3, the training circuit 1110 may include the comparator cluster 1111, the pattern generator 1112, a delay circuit 1113, a sampling circuit 1114, and a training control circuit 1115. The comparator cluster 1111 may include first through nth comparators C1 through Cn.

The pattern generator 1112 may generate the pattern data. The pattern generator 1112 may generate the plurality of reference pattern data based on the basic pattern data. The pattern generator 1112 may determine any one piece of the plurality of reference pattern data as the training pattern data. The pattern generator 1112 may provide the plurality of reference pattern data RPD to the comparator cluster 1111. The memory controller 1100 may transmit and/or send the training pattern data to the memory device 1200.

In some example embodiments, the basic pattern data may be predetermined or alternatively, the basic pattern data may be a desired basic pattern data. In some example embodiments, the basic pattern data may be a desired basic pattern data. In some example embodiments, the basic pattern data may be changed. The pattern generator 1112 may determine the basic pattern data. In some example embodiments, the pattern generator 1112 (or the memory controller 1100) may select the pattern data of a low cost as the basic pattern data. The cost may be defined by Formula 1. In some example embodiments, t and i may be integers, N may indicate the maximum or a total number of pieces of reference pattern data generated as the basic pattern data, and B may indicate the length of the basic pattern data. For example, when the basic pattern data has 16 bits, B may be ‘16’. The cost may increase as the basic pattern data becomes more similar to the reference pattern data. The pattern generator 1112 may improve the reliability of the training step by selecting the basic pattern data having a low and/or lowest cost.

$$Cost = \frac{1}{N} {\sum }_{t}^{N} {\sum }_{i}^{B} ( {T}_{0} [ i ] == {T}_{t} [ i ] ) \qquad [ Formula 1 ]$$

The delay circuit 1113 may receive a delay code DCODE from the training control circuit 1115. For example, the delay code DCODE may indicate a delay control signal. The delay code DCODE may indicate a delay amount. In some example embodiments, the delay circuit 1113 may include a plurality of delay cells for adjusting the timing of the data signal DQ. The delay circuit 1113 may control the delay amount of the data signal DQ by activating the plurality of delay cells, based on the delay code DCODE.

In some example embodiments, the delay circuit 1113 may receive pattern data PD received via the data signal DQ. The delay circuit 1113 may delay the received pattern data PD based on the delay code DCODE. The delay circuit 1113 may output delay pattern data DPD to the sampling circuit 1114.

In some example embodiments, the delay circuit 1113 may receive the data signal DQ. The delay circuit 1113 may delay the data signal DQ based on the delay code DCODE. The delay circuit 1113 may output the delayed data signal DQ to the sampling circuit 1114.

The sampling circuit 1114 may receive a clock signal. For example, the clock signal may be generated based on the data strobe signal DQS received from the memory device 1200. The sampling circuit 1114 may receive a clock signal or delayed data strobe signal DQS from a delay-locked loop (not illustrated). The sampling circuit 1114 may receive the data signal DQ from the delay circuit 1113. Alternatively, in some example embodiments, the sampling circuit 1114 may receive the delay pattern data DPD from the delay circuit 1113.

The sampling circuit 1114 may sample the delay pattern data DPD based on the clock signal, and generate sampling data SD. The sampling circuit 1114 may store the delay pattern data DPD received via the data signal DQ as the sampling data SD, and output the sampling data SD. The sampling circuit 1114 may provide the sampling data SD to the comparator cluster 1111.

The comparator cluster 1111 may receive the plurality of reference pattern data from the pattern generator 1112. The comparator cluster 1111 may receive the sampling data SD from the sampling circuit 1114. The comparator cluster 1111 may transmit and/or send the comparison result CR to the training control circuit 1115. Each of the first through nth comparators C1 through Cn may receive the sampling data SD. Each of the first through nth comparators C1 through Cn may receive the reference pattern data corresponding thereto. For example, a first comparator C1 may receive first reference pattern data, and a second comparator C2 may receive second reference pattern data.

Each of the first through nth comparators C1 through Cn may compare the reference pattern data to the sampling data, which correspond to each other, and generate the comparison result. For example, the first comparator C1 may generate a first sub-comparison result by comparing the first reference pattern data to the sampling data. The second comparator C2 may compare the second reference pattern data to the sampling data, and generate a second sub-comparison result. For example, the second comparator C2 may generate a second sub-comparison result by comparing the second reference pattern data to the sampling data. The comparator cluster 1111 may provide a comparison result including first through nth sub-comparison results to the training control circuit 1115.

In some example embodiments, each of the plurality of comparators C1 to Cn may determine whether the reference pattern data is the same as the sampling data, which corresponds to the reference pattern data. Each of the first through nth comparators C1 through Cn may compare the reference pattern data to the sampling data, which corresponds to the reference pattern data, and determine whether the reference pattern data is the same as the sampling data. When the reference pattern data is the same as the sampling data, each of the first through nth comparators C1 through Cn may output a sub-comparison result indicating a first value (for example, Pass). When the reference pattern data is different from the sampling data, each of the first through nth comparators C1 through Cn may output a sub-comparison result indicating a second value (for example, Fail).

The training control circuit 1115 may generate the delay code DCODE. The training control circuit 1115 may generate the delay code corresponding to the sub-training operation and transmit and/or send the generated delay code to the delay circuit 1113. For example, the training control circuit 1115 may increase the delay code within a maximum or total of 1 UI. The training control circuit 1115 may provide the delay code DCODE to the delay circuit 1113. The training control circuit 1115 may receive a comparison result CR from the comparator cluster 1111. The training control circuit 1115 may analyze the comparison result CR. The training control circuit 1115 may calculate the center of the window based on the comparison result CR.

In some example embodiments, the training control circuit 1115 may detect a comparator (e.g., at least one comparator of the first through nth comparators C1 through Cn), in which the sub-comparison result (or a sub-comparison result value) is changed from a first value (for example, Pass) to a second value (for example, Fail), as a left edge comparator (TPF) (hereinafter, referred to as a “pass-fail (PF) comparator”). The training control circuit 1115 may detect a comparator (e.g., at least one comparator of the first through nth comparators C1 through Cn and/or at least one other comparator of the first through nth comparators C1 through Cn), in which the sub-comparison result (or, the sub-comparison result value) is changed from the second value (for example, Fail) to the first value (for example, Pass) to a right edge comparator (TFP) (hereinafter, referred to as a “fail-pass (FP) comparator”). The training control circuit 1115 may detect a comparator (e.g., at least one comparator of the first through nth comparators C1 through Cn and/or at least one other comparator of the first through nth comparators C1 through Cn), in which the sub-comparison result (or, the sub-comparison result value) is maintained at the second value (for example, Fail), as a fail comparator (TFF) (hereinafter, referred to as an “FF comparator”). The training control circuit 1115 may detect a comparator (e.g., at least one comparator of the first through nth comparators C1 through Cn and/or at least one other comparator of the first through nth comparators C1 through Cn), in which the sub-comparison result (or, the sub-comparison result value) is maintained at the first value (for example, Pass), as a pass comparator (TPP) (hereinafter, referred to as a “PP comparator”).

In some example embodiments, the training control circuit 1115 may turn on or turn off the plurality of comparators C1 through Cn. The training control circuit 1115 may deactivate a comparator (e.g., at least one comparator of the first through nth comparators C1 through Cn) which is not used among the plurality of comparators C1 through Cn. The training control circuit 1115 may generate a plurality of comparator control signals. The comparator control signal may indicate whether a comparator (e.g., at least one comparator of the first through nth comparators C1 through Cn) corresponding thereto is activated. The training control circuit 1115 may transmit and/or send the plurality of comparator control signals to the comparator cluster 1111. The training control circuit 1115 may activate or deactivate a comparator (e.g., at least one comparator of the first through nth comparators C1 through Cn) by using the comparator control signal. For example, the training control circuit 1115 may deactivate an unused comparator among the plurality of comparators C1 through Cn by using a corresponding comparator control signal.

In some example embodiments, each of the first through nth comparators C1 through Cn may receive a corresponding comparator control signal from the training control circuit 1115. Each of the first through nth comparators C1 through Cn may be activated or deactivated in response to the comparator control signal. Each of the first through nth comparators C1 through Cn may be turned on or turned off in response to the comparator control signal.

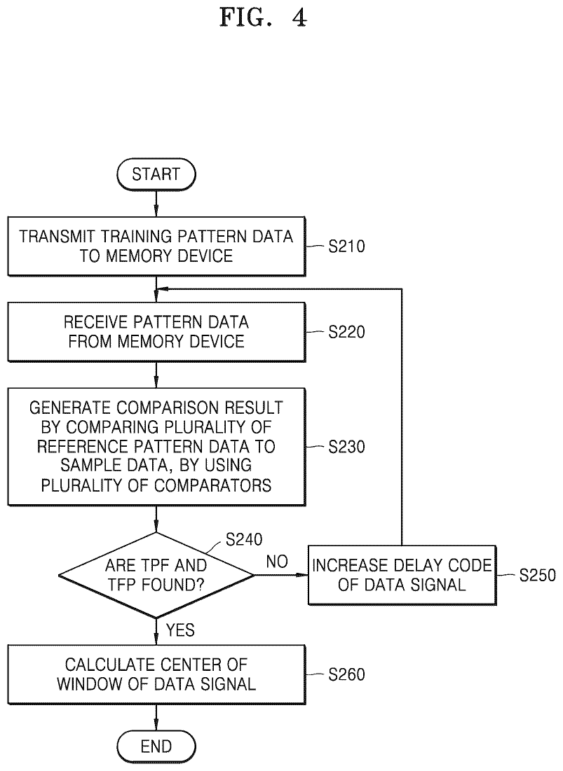

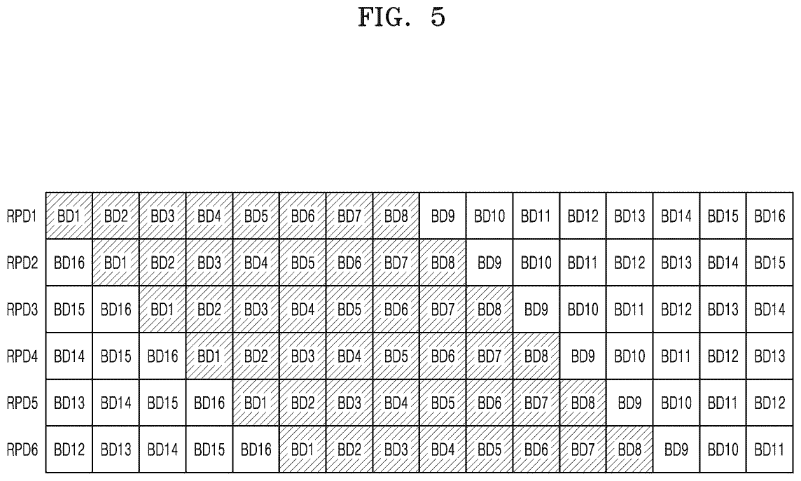

FIG. 4 is a flowchart of an operation of the memory controller 1100 in FIG. 1, according to some example embodiments.

Referring to FIGS. 1 and 4, the memory controller 1100 may perform the parallel training operation. In operation S210, the memory controller 1100 may transmit and/or send the training pattern data to the memory device 1200. The training pattern data may include any one piece of the plurality of reference pattern data. The training pattern data may be predetermined or alternatively, the training pattern data may be a desired training pattern data.

In operation S220, the memory controller 1100 may receive the pattern data PD from the memory device 1200. The memory device 1200 may receive the training pattern data. The memory controller 1100 may transmit and/or send a training command to the memory device 1200. The memory device 1200 may receive the training command. In response to the training command, the memory device 1200 may transmit and/or send a signal generated by sampling the training pattern data to the memory controller 1100 as the pattern data PD. The memory controller 1100 may receive the pattern data PD via the data signal DQ.

In operation S230, the memory controller 1100 may compare the plurality of reference pattern data to the sampling data by using the first through nth comparators C1 through Cn, and generate a comparison result. Each of the first through nth comparators C1 through Cn may perform the comparison operation of comparing the reference pattern data to the sampling data corresponding thereto. For example, the sampling data may be generated based on the received pattern data PD. The memory controller 1100 may compare the sampling data to the plurality of reference pattern data in parallel. The first comparator C1 may perform a logical operation (for example, an XOR operation) on the first reference pattern data and the sampling data. The first comparator C1 may output a logical operation result as the first sub-comparison result. While the first comparator C1 performs the logical operation, the second comparator C2 may perform a logical operation (for example, an XOR operation) on the second reference pattern data and the sampling data. The second comparator C2 may output the logical operation result as the second sub-comparison result.

In operation S240, the memory controller 1100 may determine whether the FP comparator and the PF comparator are detected. The memory controller 1100 may perform operation S260 when both the FP comparator and the PF comparator are detected, and may perform operation S250 when the FP comparator or the PF comparator is not detected (for example, when only one of the FP comparator and the PF comparator is detected, or both the FP comparator and the PF comparator are not detected). For example, the memory controller 1100 may determine whether the FP comparator and the PF comparator are detected, and in response to detecting the FP comparator and the PF comparator, the memory controller 1100 performs operation S260. The memory controller 1100 performs operation S250 in response to detecting only one of the FP comparator and the PF comparator and/or the memory controller 1100 performs operation S250 in response to not detecting either the FP comparator or the PF comparator.

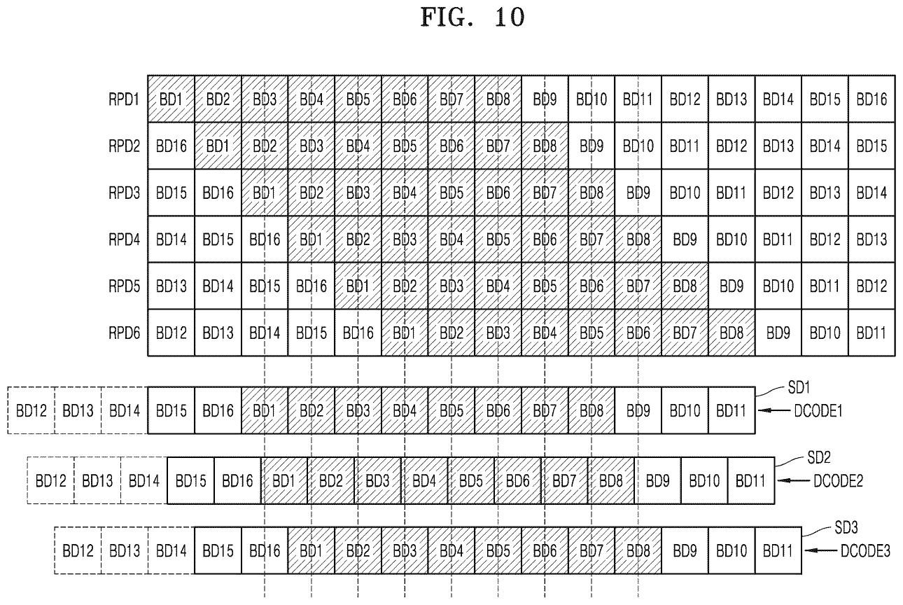

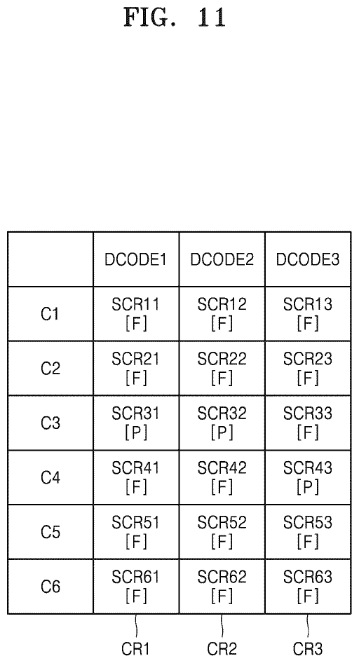

In some example embodiments, the memory controller 1100 may identify the reference pattern data in an FP state and the reference pattern data in a PF state. A more detailed description of the FP state and the PF state is given with reference to FIG. 10 according to some example embodiments. In some example embodiments, instead of detecting the FP comparator and the PF comparator, the memory controller 1100 may detect the reference pattern data in the FP state and the reference pattern data in the PF state.

In operation S250, the memory controller 1100 may increase the delay code of the data signal DQ. For example, the memory controller 1100 may increase the delay amount of the data signal DQ. Thereafter, the memory controller 1100 may perform operation S220 again.

In operation S260, the memory controller 1100 may calculate the center of the window of the data signal DQ. The memory controller 1100 may find the center of the window of the data signal DQ based on the comparison result. The memory controller 1100 may determine the final delay amount of the data signal DQ. The memory controller 1100 may determine the final delay amount of the data signal DQ, based on a first initial delay amount corresponding to the PF comparator and a second initial delay amount corresponding to the FP comparator.

As described above, according to some example embodiments, the memory controller 1100 may perform the parallel training operation. The memory controller 1100 may generate the plurality of reference pattern data, and repeatedly perform the sub-training operation based on the plurality of reference pattern data. The memory controller 1100 may determine the final delay amount of the data signal DQ based on the comparison result. Accordingly, training latency may be reduced.

FIG. 5 is a diagram of an example of the plurality of reference pattern data, according to some example embodiments.

Referring to FIGS. 1, 3, and 5, the pattern generator 1112 may generate the plurality of reference pattern data. In some example embodiments, the plurality of reference pattern data may be different from each other. The pattern generator 1112 may generate the plurality of reference pattern data used in the parallel training operation. The pattern generator 1112 may generate the plurality of reference pattern data based on the basic pattern data.

For example, the number of pieces of reference pattern data may be equal to the total number of comparators. The number of pieces of reference pattern data may be determined in advance. The number of pieces of reference pattern data may be adjusted. For example, when the length of the basic pattern data is ‘16’, the maximum or total number of pieces of reference pattern data may be ‘9’. Hereinafter, it is assumed that the length of the basic pattern data is ‘16’ and the number of pieces of reference pattern data is ‘6’.

The pattern generator 1112 may generate first through sixth reference pattern data RPD1 through RPD6. The pattern generator 1112 may obtain the basic pattern data. For example, the basic pattern data may be the same as the first reference pattern data RPD1. For example, the pattern generator 1112 may receive the basic pattern data from a CPU (not illustrated) included in the memory controller 1100. Alternatively, in some example embodiments, the pattern generator 1112 may receive the basic pattern data stored in a register included in the training circuit 1110.

In some example embodiments, the pattern generator 1112 may generate the plurality of reference pattern data by cyclically shifting the basic pattern data in UI units. The first reference pattern data RPD1 may include first through sixteenth bit data BD1 through BD16. However, example embodiments are not limited thereto, and, in some example embodiments, the number of bits of the pattern data may increase or decrease depending on an implementation. In some example embodiments, the basic pattern data (or pattern data, training pattern data, or the like) may include a basic pattern and an auxiliary pattern. For example, the basic pattern data may include bit data corresponding to the basic pattern and bit data corresponding to the auxiliary pattern.

For example, the first through eighth bit data BD1 through BD8 may constitute the basic pattern, and the ninth through sixteenth bit data BD9 through BD16 may constitute the auxiliary pattern (or a support pattern). For example, the basic pattern may include a pattern that is a main comparison reference in the comparison operation. The auxiliary pattern may include a pattern used together with the basic pattern, and may include a pattern assisting the basic pattern.

For example, the first through sixteenth bit data BD1 through BD16 may be sequentially arranged in the first reference pattern data RPD1. In other words, in the first reference pattern data RPD1, the first through sixteenth bit data BD1 through BD16 may be arranged sequentially increasing from ‘1’ to ‘16’. In the second reference pattern data RPD2, the sixteenth bit data BD16 and the first through fifteenth bit data BD1 through BD15 may be arranged sequentially. For example, the second reference pattern data RPD2 may be arranged in a form in which the sixteenth bit data BD16 is moved to the first position, and the remaining pieces of bit data (BD1 through BD15) are arranged in the existing order. For example, the second reference pattern data RPD2 may include the first through sixteenth bit data BD1 through BD16, and the first through sixteenth bit data BD1 through BD16 may have an arrangement and/or a sequence in which the sixteenth bit data BD16 is at the start (e.g., the beginning) of the second reference pattern data RPD2, the first through fifteenth bit data BD1 through BD15 are sequentially arranged subsequent to the sixteenth bit data BD16, and the fifteenth bid data BD15 is at the end of the second reference pattern data RPD2. The third reference pattern data RPD3 may be arranged in the order of the fifteenth bit data BD15, the sixteenth bit data BD16, and the first through fourteenth bit data BD1 through BD14. For example, in the third reference pattern data RPD3, after the fifteenth bit data BD15 is moved to the first position, and the sixteenth bit data BD16 is moved to the second position, the remaining pieces of bit data, or BD1 through BD14, may be arranged to keep their existing order. In the fourth reference pattern data RPD4, the fourteenth through sixteenth bit data BD14 through BD16 and the first through thirteenth bit data BD1 through BD13 may be arranged sequentially. In the fifth reference pattern data RPD5, the thirteenth through sixteenth bit data BD13 through BD16 and the first through twelfth bit data BD1 through BD12 may be arranged sequentially. In the sixth reference pattern data RPD6, the twelfth through sixteenth bit data BD12 through BD16 and the first through eleventh bit data BD1 through BD11 may be arranged sequentially. For example, each reference pattern data (e.g., RPD2 through RPD6) subsequent to the first reference pattern data RPD1 involves a rotation of the first through sixteenth bit data BD1 through BD16 to the left by at least one position of the preceding reference pattern data, such that each reference pattern data (e.g., RPD2 through RPD6) subsequent to the first reference pattern data RPD1 is a left circular shift of the bit sequence of the first through sixteenth bit data BD1 through BD16, where bits from the end of the reference pattern data are rotated to the beginning of the reference pattern data while maintaining a relative order of the remaining bits. For example, each reference pattern data (e.g., RPD2 through RPD6) shifts a starting point of the sequence of bit data BD1 through BD16 at least one bit to the left.

For example, the first reference pattern data RPD1 may include pattern data that is obtained by shifting the basic pattern data by ‘0 UI’. The second reference pattern data RPD2 may include pattern data that is obtained by shifting the basic pattern data by ‘1 UI’. The third reference pattern data RPD3 may include pattern data that is obtained by shifting the basic pattern data by ‘2 UI’. The fourth reference pattern data RPD4 may include pattern data that is obtained by shifting the basic pattern data by ‘3 UI’. The fifth reference pattern data RPD5 may include pattern data that is obtained by shifting the basic pattern data by ‘4 UI’. The sixth reference pattern data RPD6 may include pattern data that is obtained by shifting the basic pattern data by ‘5 UI’.

In some example embodiments, the memory controller 1100 may determine the sixth reference pattern data RPD6 as the training pattern data. The memory controller 1100 may transmit and/or send the sixth reference pattern data RPD6 as the training pattern data to the memory device 1200. For example, training pattern data may include data in which basic pattern data is cyclically shifted by a predetermined or alternatively, a desired maximum or total UI.

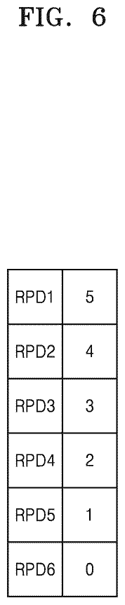

FIG. 6 is a diagram of an example of an initial delay amount of the plurality of reference pattern data, according to some example embodiments.

Referring to FIGS. 1, 5, and 6, in some example embodiments, the memory controller 1100 may determine the sixth reference pattern data RPD6 as the training pattern data. The memory controller 1100 may transmit and/or send the sixth reference pattern data RPD6 as the training pattern data to the memory device 1200. The memory device 1200 may transmit and/or send a signal generated by sampling the training pattern data to the memory controller 1100 as the pattern data PD.

In some example embodiments, the initial delay amount of each of a plurality of reference pattern data RPD1 to RPD6 may be the UI difference from the training pattern data. For example, because the sixth reference pattern data RPD6 includes the training pattern data, the initial delay amount corresponding to the sixth reference pattern data RPD6 may be ‘0 UI’. Because the fifth reference pattern data RPD5 is the same as the training pattern data when shifted by ‘1 UI’, the initial delay amount corresponding to the fifth reference pattern data RPD5 may be ‘1 UI’. Because the fourth reference pattern data RPD4 is the same as the training pattern data when shifted by ‘2 UI’, the initial delay amount corresponding to the fourth reference pattern data RPD4 may be ‘2 UI’. Because the third reference pattern data RPD3 is the same as the training pattern data when shifted by ‘3 UI’, the initial delay amount corresponding to the third reference pattern data RPD3 may be ‘3 UI’. Because the second reference pattern data RPD2 is the same as the training pattern data when shifted by ‘4 UI’, the initial delay amount corresponding to the second reference pattern data RPD2 may be ‘4 UI’. Because the first reference pattern data RPD1 is the same as the training pattern data when shifted by ‘5 UI’, the initial delay amount corresponding to the first reference pattern data RPD1 may be ‘5 UI’.

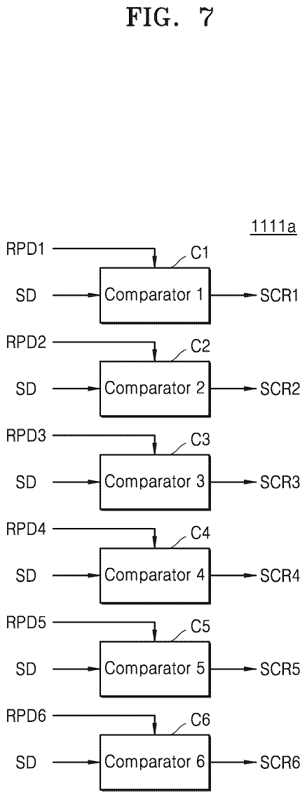

FIG. 7 is a more detailed block diagram of a comparator cluster 1111 in FIG. 1 according to some example embodiments. For example, the comparator cluster 1111a of FIG. 7 may correspond to the comparator cluster 1111 of FIG. 1.

Referring to FIGS. 1, 3, 5, and 7, the comparator cluster 1111a may include first to sixth comparators C1 through C6. The comparator cluster 1111a may receive the sampling data SD from the sampling circuit 1114. The comparator cluster 1111a may receive the plurality of reference pattern data RPD1 to RPD6 from the pattern generator 1112. The comparator cluster 1111a may transmit and/or send the comparison result CR including first through sixth sub-comparison results SCR1 through SCR6 to the training control circuit 1115.

Each of the first through sixth comparators C1 through C6 may receive the sampling data SD and the reference pattern data corresponding thereto. Each of the first through sixth comparators C1 through C6 may output a sub-comparison result corresponding thereto. For example, the first comparator C1 may receive the sampling data SD and the first reference pattern data RPD1. The first comparator C1 may output the first sub-comparison result SCR1 to the training control circuit 1115. The second comparator C2 may receive the sampling data SD and the second reference pattern data RPD2. The second comparator C2 may output the second sub-comparison result SCR2 to the training control circuit 1115. The third comparator C3 may receive the sampling data SD and the third reference pattern data RPD3. The third comparator C3 may output the third sub-comparison result SCR3 to the training control circuit 1115.

The fourth comparator C4 may receive the sampling data SD and the fourth reference pattern data RPD4. The fourth comparator C4 may output the fourth sub-comparison result SCR4 to the training control circuit 1115. The fifth comparator C5 may receive the sampling data SD and the fifth reference pattern data RPD5. The fifth comparator C5 may output the fifth sub-comparison result SCR5 to the training control circuit 1115. The sixth comparator C6 may receive sampling data SD and sixth reference pattern data RPD6. The sixth comparator C6 may output the sixth sub-comparison result SCR6 to the training control circuit 1115.

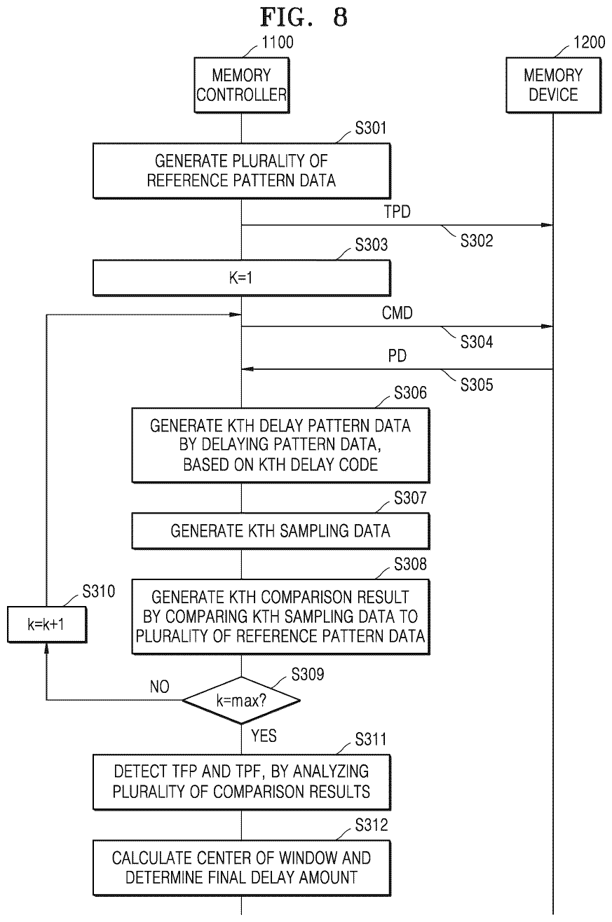

FIG. 8 is a flowchart of an operation of the memory system 1000 in FIG. 1, according to some example embodiments.

Referring to FIGS. 1 and 8, the memory system 1000 may perform the parallel training operation. The parallel training operation may include a plurality of sub-training operations. The memory system 1000 may repeatedly perform the sub-training operation.

In some example embodiments, the training circuit 1110 may generate the plurality of reference pattern data and repeatedly perform the sub-training operation based on the plurality of reference pattern data. The training circuit 1110 may find the center of the window based on the comparison result generated in the sub-training operation. For example, the sub-training operation may be referred to as an operation of receiving the pattern data from memory device 1200, comparing sampling data to the plurality of reference pattern data at the same time, and generating the comparison result. In other words, the sub-training operation may be referred to as an operation in which an operation of accessing the memory device 1200 for training is combined with an operation of comparing the read pattern data to the reference data. The memory system 1000 may repeatedly perform the sub-training operation while changing the delay code. In some example embodiments, the training circuit 1110 may perform a plurality of sub-training operations within ‘1 UI’.

In operation S301, the memory controller 1100 may generate the plurality of reference pattern data. The memory controller 1100 may generate the plurality of reference pattern data based on the basic pattern data. In operation S302, the memory controller 1100 may transmit and/or send the training pattern data to the memory device 1200. The memory controller 1100 may determine any one piece of the plurality of reference pattern data as the training pattern data. The memory controller 1100 may transmit and/or send the training pattern data to the memory device 1200. The memory device 1200 may receive the training pattern data.

In operation S303, a variable k may be set to 1. In some example embodiments, the variable k may be used to describe repetition of the sub-training operation, and does not limit the scope of the inventive concepts. The sub-training operation may include operation S304 through operation S310.

In operation S304, the memory controller 1100 may transmit and/or send the training command to the memory device 1200. For example, the training command may include a read data signal DQ training command. In some example embodiments, the memory controller 1100 may transmit and/or send the training pattern data together with the training command to the memory device 1200. The memory device 1200 may receive the training command.

In operation S305, the memory device 1200 may transmit and/or send the pattern data PD to the memory controller 1100. The memory device 1200 may transmit and/or send a signal generated by sampling training pattern data TPD to the memory controller 1100 as the pattern data PD. The memory controller 1100 may receive the pattern data PD.

In operation S306, the memory controller 1100 may delay the pattern data PD based on a kth delay code. The memory controller 1100 may delay the pattern data PD by a delay amount corresponding to the kth delay code. Alternatively, in some example embodiments the memory controller 1100 may delay the data signal DQ by a delay amount corresponding to the kth delay code. The memory controller 1100 may generate kth delay pattern data DPD. For example, in operation S306, the memory controller 1100 generates kth delay pattern data DPD by delaying the pattern data PD based on the kth delay code. In operation S307, the memory controller 1100 may generate kth sampling data. The memory controller 1100 may generate kth sampling data by sampling kth delay pattern data, based on the clock signal.

In operation S308, the memory controller 1100 may compare the kth sampling data to the plurality of reference pattern data, and generate a kth comparison result. Each of the plurality of comparators included in the memory controller 1100 may compare the kth sampling data to the reference pattern data corresponding thereto. In other words, the memory controller 1100 may compare the sampling data to the plurality of reference pattern data at the same time. The memory controller 1100 may generate the kth comparison result indicating whether the kth sampling data is the same as the plurality of reference pattern data.

In operation S309, the memory controller 1100 may determine whether the variable k is a maximum value or total value. For example, the maximum value or total value may be a predetermined or alternatively, a desired value. The memory controller 1100 may adjust the delay amount of the data signal in units of delay steps. ‘1 UI’ may be expressed as a product of the maximum value or total value and the delay step (1UI=maximum value (or total value)*delay step). The maximum value or total value may be determined based on the number of delay steps in 1 UI. For example, the delay step may indicate a delay amount (or a delay value) that increases as the delay code increases by ‘1’.

In some example embodiments, when the variable k is not the maximum value or total value, the variable k may be increased by ‘l’ in operation S310. Thereafter, the memory controller 1100 may perform operation S304. The memory controller 1100 may repeatedly perform the sub-training operation. When the variable k is the maximum value or total value, the memory controller 1100 may perform operation S311.

In operation S311, the memory controller 1100 may detect the FP comparator TFP and the PF comparator TPF by analyzing a plurality of comparison results. The memory controller 1100 may detect the left edge and the right edge of the window based on the plurality of comparison results. Alternatively, in some example embodiments, the memory controller 1100 may detect the reference pattern data in the FP state and the reference pattern data in the PF state.

In operation S312, the memory controller 1100 may calculate the center of the window, based on the FP comparator TFP and the PF comparator TPF. Alternatively, in some example embodiments, the memory controller 1100 may calculate the center of the window, based on the reference pattern data in the FP state and the reference pattern data in the PF state. Accordingly, the memory controller 1100 may determine the final delay amount of the data signal DQ.

As described above, the memory controller 1100 may perform a comparison operation on the plurality of reference pattern data and sampling data in parallel by using the plurality of comparators. Accordingly, in some example embodiments, the memory controller 1100 may simultaneously perform training in units of delay steps and training in units of UIs.

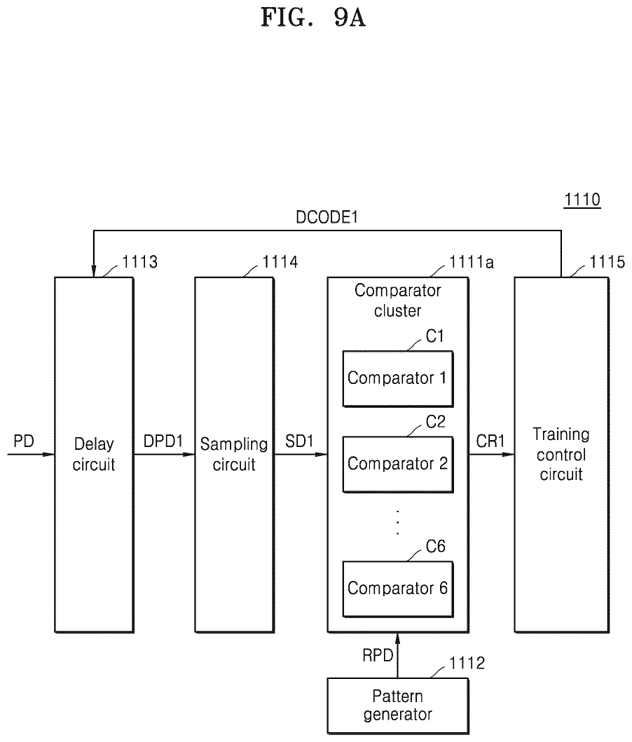

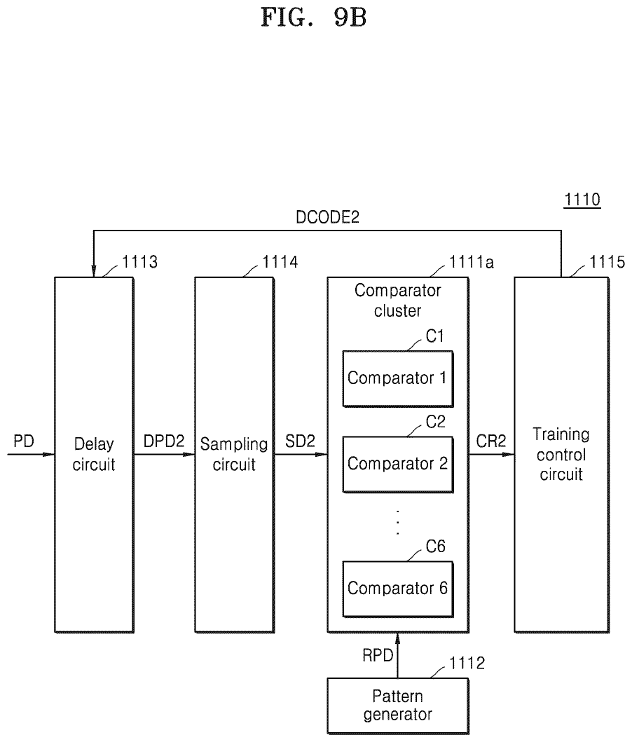

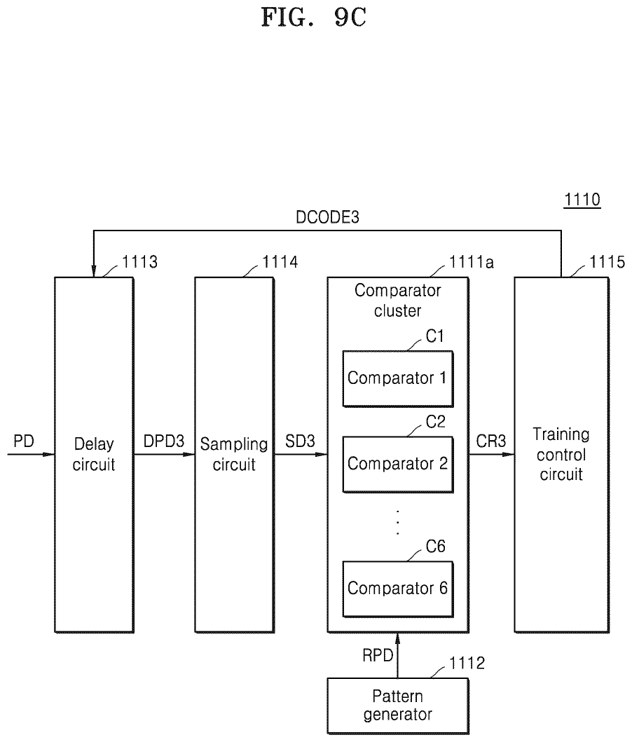

FIGS. 9A through 9C are diagrams for describing operations of the memory controller 1100 in FIG. 1, according to some example embodiments.

Referring to FIGS. 9A through 9C, the training circuit 1110 may include a comparator cluster 1111a, the pattern generator 1112, the delay circuit 1113, the sampling circuit 1114, and the training control circuit 1115. The comparator cluster 1111a may include the first through sixth comparators C1 through C6. The training circuit 1110 may repeatedly perform the plurality of sub-training operations while changing the delay code. The training circuit 1110 may perform the parallel training operation while changing the delay code in the ‘1 UI’.

For example, the training circuit 1110 may perform first through third sub-training operations. However, example embodiments are not limited thereto, and, in some example embodiments, the number of sub-training operations in the parallel training operation may be increased or decreased according to implementation. Referring to FIG. 9A, the delay code corresponding to the first sub-training operation may include a first delay code DCODE1. The first delay code DCODE1 may include an initial delay code. Referring to FIG. 9B, the delay code corresponding to the second sub-training operation may include a second delay code DCODE2. Referring to FIG. 9C, the delay code corresponding to the third sub-training operation may include a third delay code DCODE3. The third delay code DCODE3 may include a final delay code. For example, the difference between the delay amount of the final delay code and the delay amount of the initial delay code may be a maximum or total of ‘1 UI’. The training circuit 1110 may perform the first sub-training operation. The delay circuit 1113 may receive the pattern data PD from the memory device 1200. The delay circuit 1113 may receive the first delay code DCODE1 from the training control circuit 1115. The delay circuit 1113 may delay the pattern data PD based on the first delay code DCODE1. Alternatively, in some example embodiments, the delay circuit 1113 may delay the data signal DQ based on the first delay code DCODE1. The delay circuit 1113 may delay the pattern data PD by a delay amount corresponding to the first delay code DCODE1. The delay circuit 1113 may generate first delay pattern data DPD1. The delay circuit 1113 may transmit and/or send the first delay pattern data DPD1 to the sampling circuit 1114.

The sampling circuit 1114 may receive the first delay pattern data DPD1. The sampling circuit 1114 may receive a clock signal generated based on the data strobe signal DQS. The sampling circuit 1114 may generate first sampling data SD1 by sampling the first delay pattern data DPD1, based on the clock signal. The sampling circuit 1114 may transmit and/or send the first sampling data SD1 to the comparator cluster 1111a.

The comparator cluster 1111a may simultaneously compare the first sampling data SD1 to the plurality of reference pattern data RPD. For example, the first comparator C1 may determine whether the first sampling data SD1 is the same as the first reference pattern data RPD1 during a first time period. The first comparator C1 may generate the first sub-comparison result indicating whether the first sampling data SD1 is the same as the first reference pattern data RPD1. The second comparator C2 may determine whether the first sampling data SD1 is the same as the second reference pattern data RPD2 during the first time period. The second comparator C2 may generate the second sub-comparison result indicating whether the first sampling data SD1 is the same as the second reference pattern data RPD2. The comparator cluster 1111a may transmit and/or send a first comparison result CR1 including first through sixth sub-comparison results to the training control circuit 1115.

The training control circuit 1115 may update the current delay code to the second delay code DCODE2. The training control circuit 1115 may transmit and/or send the second delay code DCODE2 to the delay circuit 1113.

Referring to FIG. 9B, the training circuit 1110 may perform the second sub-training operation. The delay circuit 1113 may receive the pattern data PD from the memory device 1200. The delay circuit 1113 may receive the second delay code DCODE2 from the training control circuit 1115. The delay circuit 1113 may delay the pattern data PD based on the second delay code DCODE2. The delay circuit 1113 may delay the pattern data PD by a delay amount corresponding to the second delay code DCODE2. The delay circuit 1113 may generate second delay pattern data DPD2. The delay circuit 1113 may transmit and/or send the second delay pattern data DPD2 to the sampling circuit 1114.

The sampling circuit 1114 may receive the second delay pattern data DPD2. The sampling circuit 1114 may receive the clock signal. The sampling circuit 1114 may generate second sampling data SD2 by sampling the second delay pattern data DPD2, based on the clock signal. The sampling circuit 1114 may transmit and/or send the second sampling data SD2 to the comparator cluster 1111a.

The comparator cluster 1111a may simultaneously compare the second sampling data SD2 to the plurality of reference pattern data RPD. For example, the first comparator C1 may determine whether the second sampling data SD2 is the same as the first reference pattern data RPD1 during a second time period. The first comparator C1 may generate the first sub-comparison result indicating whether the second sampling data SD2 is the same as the first reference pattern data RPD1. The second comparator C2 may determine whether the second sampling data SD2 is the same as the second reference pattern data RPD2 during the second time period. The second comparator C2 may generate the second sub-comparison result indicating whether the second sampling data SD2 is the same as the second reference pattern data RPD2. The comparator cluster 1111a may transmit and/or send a second comparison result CR2 including first through sixth sub-comparison results to the training control circuit 1115.

The training control circuit 1115 may update the current delay code to the third delay code DCODE3. The training control circuit 1115 may transmit and/or send the third delay code DCODE3 to the delay circuit 1113.

Referring to FIG. 9C, the training circuit 1110 may perform the third sub-training operation. The delay circuit 1113 may receive the pattern data PD from the memory device 1200. The delay circuit 1113 may receive the third delay code DCODE3 from the training control circuit 1115. The delay circuit 1113 may delay the pattern data PD based on the third delay code DCODE3. The delay circuit 1113 may delay the pattern data PD by a delay amount corresponding to the third delay code DCODE3. The delay circuit 1113 may generate third delay pattern data DPD3. The delay circuit 1113 may transmit and/or send the third delay pattern data DPD3 to the sampling circuit 1114.

The sampling circuit 1114 may receive the third delay pattern data DPD3. The sampling circuit 1114 may receive the clock signal. The sampling circuit 1114 may generate third sampling data SD3 by sampling the third delay pattern data DPD3, based on the clock signal. The sampling circuit 1114 may transmit and/or send the third sampling data SD3 to the comparator cluster 1111a.

The comparator cluster 1111a may simultaneously compare the third sampling data SD3 to the plurality of reference pattern data RPD. For example, the first comparator C1 may determine whether the third sampling data SD3 is the same as the first reference pattern data RPD1 during a third time period. The first comparator C1 may generate the first sub-comparison result indicating whether the third sampling data SD3 is the same as the first reference pattern data RPD1. The second comparator C2 may determine whether the third sampling data SD3 is the same as the second reference pattern data RPD2 during the third time period. The second comparator C2 may generate the second sub-comparison result indicating whether the third sampling data SD3 is the same as the second reference pattern data RPD2. The comparator cluster 1111a may transmit and/or send a third comparison result CR3 including first through sixth sub-comparison results to the training control circuit 1115.

FIG. 10 is a diagram of examples of reference pattern data and sampling data, according to some example embodiments. FIG. 11 is a diagram of a comparison result according to some example embodiments.

Referring to FIGS. 1, 9A, 9B, 9C, 10, and 11, the comparator cluster 1111a may perform a comparison operation on sampling data and a plurality of reference pattern data. Each of the first through sixth comparators C1 through C6 may perform a comparison operation by using different pieces of reference pattern data. For example, the data signal DQ may precede the data strobe signal DQS. The memory controller 1100 may fail to sample the twelfth through fourteenth bit data BD12 through BD14 from the pattern data PD. The memory controller 1100 may sample only the fifteenth bit data BD15, the sixteenth bit data BD16, and the first through eleventh bit data BD1 through BD11 from the pattern data PD. The first through third sampling data SD1 through SD3 may include only the fifteenth bit data BD15, the sixteenth bit data BD16, and the first through eleventh bit data BD1 through BD11. However, example embodiments are not limited thereto.

During the first time period, the first comparator C1 may compare the first sampling data SD1 to the first reference pattern data RPD1. Because the first sampling data SD1 is not the same as the first reference pattern data RPD1 the first comparator C1 may output a sub-comparison result SCR11 indicating the second value (for example, Fail).

During the first time period, the second comparator C2 may compare the first sampling data SD1 to the second reference pattern data RPD2. Because the first sampling data SD1 is not the same as the second reference pattern data RPD2, the second comparator C2 may output a sub-comparison result SCR21 indicating the second value (for example, Fail).

During the first time period, the third comparator C3 may compare the first sampling data SD1 to the third reference pattern data RPD3. Because the first sampling data SD1 is the same as the third reference pattern data RPD3, the third comparator C3 may output a sub-comparison result SCR31 indicating the first value (for example, Pass).

During the first time period, the fourth comparator C4 may compare the first sampling data SD1 to the fourth reference pattern data RPD4. Because the first sampling data SD1 is not the same as the fourth reference pattern data RPD4, the fourth comparator C4 may output a sub-comparison result SCR41 indicating the second value (for example, Fail).

During the first time period, the fifth comparator C5 may compare the first sampling data SD1 to the fifth reference pattern data RPD5. Because the first sampling data SD1 is not the same as the fifth reference pattern data RPD5, the fifth comparator C5 may output a sub-comparison result SCR51 indicating the second value (for example, Fail).

During the first time period, the sixth comparator C6 may compare the first sampling data SD1 to the sixth reference pattern data RPD6. Because the first sampling data SD1 is not the same as the sixth reference pattern data RPD6, the sixth comparator C6 may output a sub-comparison result SCR61 indicating the second value (for example, Fail).

During the second time period, the first comparator C1 may compare the second sampling data SD2 to the first reference pattern data RPD1. Because the second sampling data SD2 is not the same as the first reference pattern data RPD1, the first comparator C1 may output a sub-comparison result SCR12 indicating the second value (for example, Fail).

During the second time period, the second comparator C2 may compare the second sampling data SD2 to the second reference pattern data RPD2. Because the second sampling data SD2 is not the same as the second reference pattern data RPD2 the second comparator C2 may output a sub-comparison result SCR22 indicating the second value (for example, Fail).

During the second time period, the third comparator C3 may compare the second sampling data SD2 to the third reference pattern data RPD3. Because the second sampling data SD2 is the same as the third reference pattern data RPD3, the third comparator C3 may output a sub-comparison result SCR32 indicating the first value (for example, Pass).

During the second time period, the fourth comparator C4 may compare the second sampling data SD2 to the fourth reference pattern data RPD4. Because the second sampling data SD2 is not the same as the fourth reference pattern data RPD4, the fourth comparator C4 may output a sub-comparison result SCR42 indicating the second value (for example, Fail).

During the second time period, the fifth comparator C5 may compare the second sampling data SD2 to the fifth reference pattern data RPD5. Because the second sampling data SD2 is not the same as the fifth reference pattern data RPD5, the fifth comparator C5 may output a sub-comparison result SCR52 indicating the second value (for example, Fail).

During the second time period, the sixth comparator C6 may compare the second sampling data SD2 to the sixth reference pattern data RPD6. Because the second sampling data SD2 is not the same as the sixth reference pattern data RPD6, the sixth comparator C6 may output a sub-comparison result SCR62 indicating the second value (for example, Fail).

During the third time period, the first comparator C1 may compare the third sampling data SD3 to the first reference pattern data RPD1. Because the third sampling data SD3 is not the same as the first reference pattern data RPD1, the first comparator C1 may output a sub-comparison result SCR13 indicating the second value (for example, Fail).

During the third time period, the second comparator C2 may compare the third sampling data SD3 to the second reference pattern data RPD2. Because the third sampling data SD3 is not the same as the second reference pattern data RPD2 the second comparator C2 may output a sub-comparison result SCR23 indicating the second value (for example, Fail).

During the third time period, the third comparator C3 may compare the third sampling data SD3 to the third reference pattern data RPD3. Because the third sampling data SD3 is not the same as the third reference pattern data RPD3 the third comparator C3 may output a sub-comparison result SCR33 indicating the second value (for example, Fail).

During the third time period, the fourth comparator C4 may compare the third sampling data SD3 to the fourth reference pattern data RPD4. Because the third sampling data SD3 is the same as the fourth reference pattern data RPD4, the fourth comparator C4 may output a sub-comparison result SCR43 indicating the first value (for example, Pass).

During the third time period, the fifth comparator C5 may compare the third sampling data SD3 to the fifth reference pattern data RPD5. Because the third sampling data SD3 is not the same as the fifth reference pattern data RPD5 the fifth comparator C5 may output a sub-comparison result SCR53 indicating the second value (for example, Fail).

During the third time period, the sixth comparator C6 may compare the third sampling data SD3 to the sixth reference pattern data RPD6. Because the third sampling data SD3 is not the same as the sixth reference pattern data RPD6 the sixth comparator C6 may output a sub-comparison result SCR63 indicating the second value (for example, Fail).

The comparator cluster 1111a may provide the first comparison result CR1 to the training control circuit 1115. The first comparison result CR1 may include sub-comparison results SCR11, SCR21, SCR31, SCR41, SCR51, and SCR61. The comparator cluster 1111 may provide the second comparison result CR2 to the training control circuit 1115. The second comparison result CR2 may include sub-comparison results SCR12, SCR22, SCR32, SCR42, SCR52, and SCR62. The comparator cluster 1111 may provide the third comparison result CR3 to the training control circuit 1115. The third comparison result CR3 may include sub-comparison results SCR13, SCR23, SCR33, SCR43, SCR53, and SCR63.

In some example embodiments, the training circuit 1110 may determine the state of a comparator by analyzing a plurality of comparison results. A comparator may be categorized as one of an FP comparator TFP, a PF comparator TPF, a fail comparator TFF, and a pass comparator TPP, depending on states of the comparator. For example, the fail comparator TFF may include the first comparator C1, the second comparator C2, the fifth comparator C5, and the sixth comparator C6. The PF comparator TPF may include the third comparator C3, and the FP comparator TFP may include the fourth comparator C4. For example, because each of the comparison results SCR11, SCR12, and SCR13 of the first comparator C1 indicate the second value (e.g., Fail), the first comparator C1 may be categorized as a fail comparator TFF. Similarly, because the comparison results of each of the second comparator C2, the fifth comparator C5, and the sixth comparator C6 indicate the second value (e.g., Fail), each of the second comparator C2, the fifth comparator C5, and the sixth comparator C6 may be categorized as fail comparators TFFs.

In some example embodiments, the training circuit 1110 may determine the state of the reference pattern data, by analyzing the comparison result. The state of the reference pattern data may be the same as or similar to the state of the comparator. The state of the reference pattern data may include the PF state, the FP state, an FF state, and a PP state. Similar to the state of the comparator, the reference pattern data in which the comparison result is changed from the first value (for example, Pass) to the second value (for example, Fail) may have the PF state. The reference pattern data in which the comparison result is changed from the second value (for example, Fail) to the first value (for example, Pass) may have the FP state. The reference pattern data in which the comparison result is maintained at the second value (for example, Fail) may have the FF state. The reference pattern data in which the comparison result is maintained as the first value (for example, Pass) may have the PP state.

For example, the first reference pattern data RPD1, the second reference pattern data RPD2, the fifth reference pattern data RPD5, and the sixth reference pattern data RPD6 may be in the FF state. The third reference pattern data RPD3 may be in the PF state, and the fourth reference pattern data RPD4 may be in the FP state.

The training circuit 1110 may determine the left edge of the reference pattern data in the FP state as the left edge of the data signal DQ. The training circuit 1110 may determine the right edge of the reference pattern data in the PF state as the right edge of the data signal DQ. For example, the left edge of the fourth reference pattern data RPD4 may be detected as the left edge of the data signal DQ. The right edge of the third reference pattern data RPD3 may be detected as the right edge of the data signal DQ. The training circuit 1110 may calculate the final delay amount, based on the initial delay amount of reference pattern data corresponding to the FP state (for example, fourth reference pattern data RPD4). The training circuit 1110 may detect the center of the window.

In some example embodiments, the training circuit 1110 may perform the plurality of sub-training operations while changing (or increasing) the delay code. For example, the training circuit 1110 may determine the reference pattern data in which the comparison result changes from the second value (for example, Fail) to the first value (for example, Pass).

For example, the training circuit 1110 may determine that the comparison result of the fourth reference pattern data RPD4 is the second value (for example, Fail). The training circuit 1110 may determine a time point at which the comparison result corresponding to the fourth reference pattern data RPD4 changes from the second value (for example, Fail) to the first value (for example, Pass) or the delay code corresponding to the time point. In relation to the fourth reference pattern data RPD4, the training circuit 1110 may determine, as the first delay code, the delay code corresponding to the sub-training operation in which the comparison result indicates the first value (for example, Pass) for the first time in the plurality of sub-training operations. The training circuit 1110 may add the delay amount corresponding to the first delay code and the initial delay amount of the fourth reference pattern data RPD4, and determine a left detection time point indicating the left edge.

For example, the training circuit 1110 may determine the reference pattern data in which the comparison result changes from the first value (for example, Pass) to the second value (for example, Fail). For example, the training circuit 1110 may determine that the comparison result of the third reference pattern data RPD3 is the first value (for example, Pass). Thereafter, the training circuit 1110 may determine a time point or a delay code at which the comparison result corresponding to the third reference pattern data RPD3 changes from the first value (for example, Pass) to the second value (for example, Fail). In relation to the third reference pattern data RPD3, the training circuit 1110 may determine, as the second delay code, a delay code corresponding to the sub-training operation in which the comparison result indicates the second value (for example, Fail) for the first time in the plurality of sub-training operations. The training circuit 1110 may add the delay amount corresponding to the second delay code and the initial delay amount of the third reference pattern data RPD3, and determine the right edge as a right detection time point.

For example, the training circuit 1110 may detect the center of the window, based on the left detection time point and the right detection time point. For example, the training circuit 1110 may determine an average of the left detection time point and the right detection time point as the center time point of the window. The training circuit 1110 may determine the center time point of the window as the final delay amount of the data signal DQ.

The training circuit 1110 may simultaneously compare the plurality of reference pattern data to the sampling data, by using the first through sixth comparators C1 through C6. Accordingly, the training circuit 1110 may adjust the delay amount to move within the maximum or total ‘1 UI’, but by using the first through sixth comparators C1 through C6, the effect of performing the training as much as ‘the total number of comparators x UI’ may be obtained. In other words, although the delay amount has been adjusted within the ‘1 UI’ range, the effect of adjusting the delay amount within the ‘6 UI’ range may be obtained, by using the parallel structure. Thus, according to some example embodiments, the training time may be reduced, and the training range may be increased and/or improved.

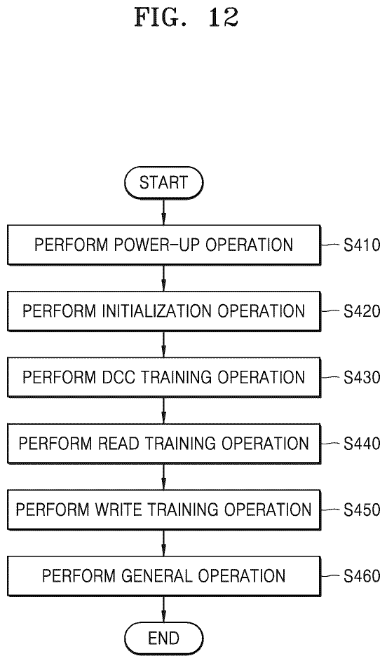

FIG. 12 is a flowchart of an example of an operation of the memory system 1000 in FIG. 1, according to some example embodiments.

An initialization operation and/or a boot-up operation of the memory system 1000 is described with reference to FIG. 12. Referring to FIGS. 1 and 12, the memory system 1000 may perform a power-up operation in operation S410. In operation S420, the memory system 1000 may perform the initialization operation. The memory controller 1100 and the memory device 1200 may perform the initialization operation according to a predetermined or alternatively, a desired manner. During the initialization operation, the memory controller 1100 may provide a power voltage to the memory device 1200, perform various initial setting operations, and read and/or set necessary or alternatively, desired information from the memory device 1200.

The initialization operation may include a ZQ calibration operation. The memory system 1000 may perform the ZQ calibration operation. The ZQ calibration operation may be referred to as an operation of adjusting the strength of output drivers connected to the data signal DQ or other signal lines to provide high data integrity, or an operation of setting an on-die termination (ODT) value.

In operation S430, the memory system 1000 may perform a duty correction circuit (DCC) training operation. The memory device 1200 may output data via the data signal DQ in synchronization with a rising edge and a falling edge of the data strobe signal DQS. The windows of the data signal DQ may correspond to a logic high interval and a logic low interval of the data strobe signal DQS, respectively. Because the data strobe signal is generated based on a read enable signal/RE, the windows of the data signal DQ may be determined according to a ratio of the logic high interval to the logic low interval of the read enable signal/RE.

A duty mismatch may occur. In other words, because the logic high interval and the logic low interval of the read enable signal/RE are different from each other, windows of the data signal DQ may be different from each other, and thus a valid window may not be secured. Accordingly, by performing a DCC training operation, duty correction may be performed on the clock signal such as the read enable signal/RE to secure a valid data window.

In operation S440, the memory system 1000 may perform a read training operation. For example, the memory controller 1100 may adjust the setting values of the memory device 1200 and the memory controller 1100 so that the signal integrity of data read from the memory device 1200 or the center (or data-eye) of the window is optimized. For example, the read training operation may be performed independently on each of first through nth data lines DQ1 through DQn.

In operation S450, the memory system 1000 may perform a write training operation. The write training operation may include transmit and/or transmitter (TX) side write training and receive and/or receiver (RX) side write training. The TX side write training may be omitted. For example, the memory controller 1100 may transmit and/or send data to the memory device 1200, and adjust set values of the memory controller 1100 and the memory device 1200 so that the signal integrity of the transmitted and/or sent data or the center of the window (or, data-eye) is optimized. For example, the write training operation may be performed independently on each of the first through nth data lines DQ1 through DQn. After the initialization operation or the training operation in operations S410 through S450 is performed as described above, in operation S460, the memory system 1000 may perform a normal operation (or a general operation) based on the training result.

The trainings performed in operations S430, S440, and S450 may indicate data training (DQ training). The parallel training operation described with reference to FIGS. 1 through 11, according to some example embodiments, may be applied to the trainings performed in operations S430, S440, and S450.

In some example embodiments, the trainings performed in operations S430, S440, and S450 may refer to the results of each other. For example, when the write training is performed in operation S450, the read operation may be performed based on the training result of the read operation performed in step S440, and the data integrity may be secured.

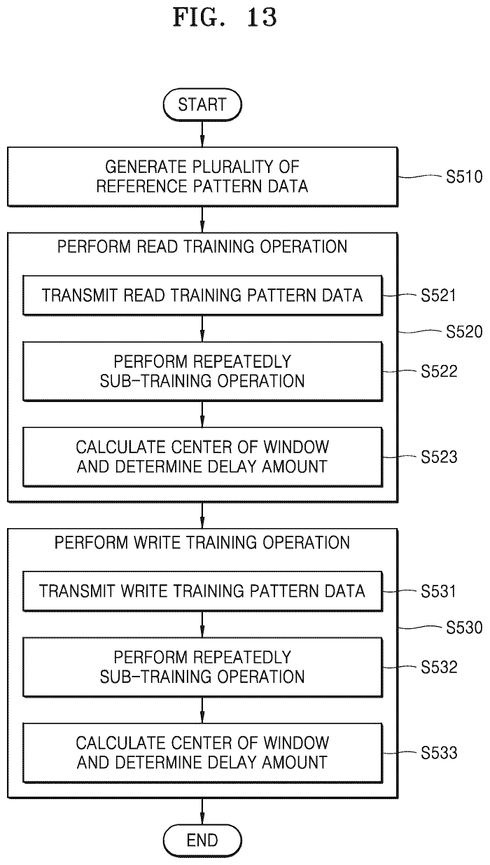

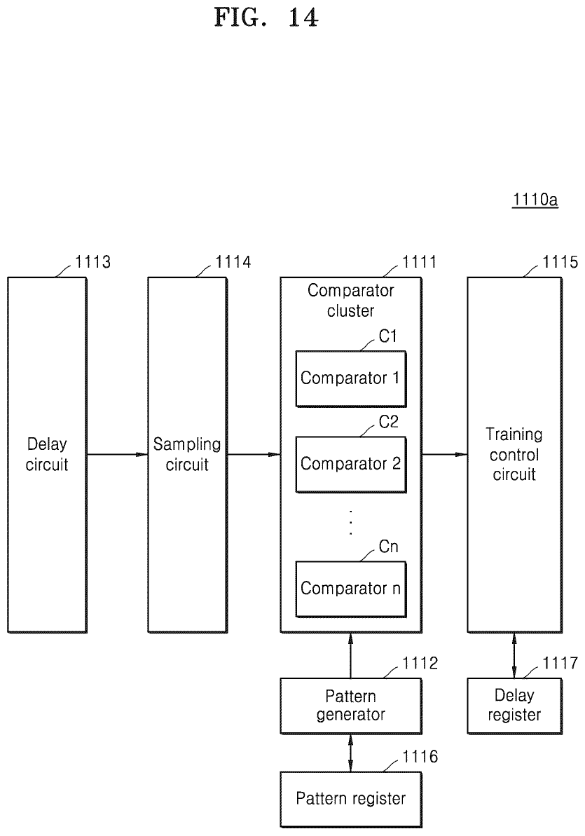

FIG. 13 is a flowchart of an example of an operation of the memory controller 1100 in FIG. 1, according to some example embodiments.

Referring to FIGS. 1, 12, and 13, the memory controller 1100 may perform the read training operation and the write training operation. For the write training operation, the memory controller 1100 may write pattern data to the memory device 1200 and read the written pattern data. For the read training operation, the memory controller 1100 may read pattern data stored in the memory device 1200. The memory controller 1100 may compare the read pattern data to the plurality of reference pattern data, and depending on the comparison result, may determine the center position of the window.

In operation S510, the memory controller 1100 may generate the plurality of reference pattern data. The memory controller 1100 may generate the plurality of reference pattern data by cyclically shifting the basic pattern data.

In operation S520, the memory controller 1100 may perform the read training operation. Operation S520 may include operations S521 through S523. In operation S521, the memory controller 1100 may transmit and/or send read training pattern data to the memory device 1200. The memory controller 1100 may transmit and/or send one piece of the plurality of reference pattern data to the memory device 1200 as the read training pattern data. In operation S522, the memory controller 1100 may repeatedly perform the sub-training operation. The memory controller 1100 may perform the sub-training operation while changing the delay code. The memory controller 1100 may generate the comparison result while simultaneously comparing the sampling data to the plurality of reference pattern data.

In operation S523, the memory controller 1100 may calculate the center of the window, and determine the delay amount, e.g., the final delay amount. The memory controller 1100 may find the center of the window, based on the comparison result. The memory controller 1100 may determine the final delay amount corresponding to the center of the window. The memory controller 1100 may apply the final delay amount to the data signal DQ. Alternatively, in some example embodiment the memory controller 1100 may adjust the delay amount of the data strobe signal DQS, based on the final delay amount.

The memory controller 1100 may determine the delay amount of the read training operation as a read final delay amount. For example, the read final delay amount may be defined by Formula 2. Dfr may indicate the read final delay amount, Di may indicate the initial delay amount of the reference pattern data in the FP state, and Dc may indicate a fine delay amount. For example, the fine delay amount may be referred to as the delay amount in which the comparison result is changed from the first value (for example, Pass) to the second value (for example, Fail) or from the second value (Fail) to the first value (for example, Pass) in the plurality of sub-training operations.

$$Dfr = 1 UI \times Di + Dc \qquad [ Formula 2 ]$$

In operation S530, the memory controller 1100 may perform the write training operation. Operation S530 may include operations S531 through S533. In operation S531, the memory controller 1100 may transmit and/or send the write training pattern data to the memory device 1200. The memory controller 1100 may transmit and/or send one piece of the plurality of reference pattern data to the memory device 1200 as the write training pattern data. In operation S532, the memory controller 1100 may repeatedly perform the sub-training operation. The memory controller 1100 may perform the sub-training operation while changing the delay code. The memory controller 1100 may generate the comparison result while simultaneously comparing the sampling data to the plurality of reference pattern data.

In operation S533, the memory controller 1100 may calculate the center of the window, and determine the final delay amount. The memory controller 1100 may find the center of the window, based on the comparison result. The memory controller 1100 may determine the final delay amount corresponding to the center of the window. The memory controller 1100 may apply the final delay amount to the data signal DQ. Alternatively, in some example embodiments, the memory controller 1100 may adjust the delay amount of the data strobe signal DQS, based on the final delay amount.

The memory controller 1100 may determine the delay amount of the write training operation as a write final delay amount. For example, the write final delay amount may be defined by Formula 3. Dfw may indicate the write final delay amount, Di may indicate the initial delay amount of the reference pattern data in the FP state, and Dc may indicate the fine delay amount. For example, the fine delay amount may be referred to as the delay amount in which the comparison result is changed from the first value (for example, Pass) to the second value (for example, Fail) or from the second value (for example, Fail) to the first value (for example, Pass) in the plurality of sub-training operations.

$$Dfw = 1 UI \times Di + Dc \qquad [ Formula 3 ]$$

FIG. 14 is a more detailed block diagram of the training circuit 1110 in FIG. 1 according to some example embodiments.

Referring to FIGS. 1 and 14, a training circuit 1110a may include the comparator cluster 1111, the pattern generator 1112, the delay circuit 1113, the sampling circuit 1114, the training control circuit 1115, a pattern register 1116, and a delay register 1117. The comparator cluster 1111 may include the first through nth comparators C1 through Cn. For convenience of descriptions, duplicate descriptions of components given above are omitted.

The pattern data may be stored in the pattern register 1116. For example, at least one of the basic pattern data, the plurality of reference pattern data, and the training pattern data may be stored in the pattern register 1116. In some example embodiments, the pattern generator 1112 may generate the plurality of reference pattern data based on the basic pattern data and store the plurality of reference pattern data in the pattern register 1116. The pattern generator 1112 may determine any one piece of the plurality of reference pattern data as the training pattern data. The pattern generator 1112 may store the determined training pattern data in the pattern register 1116.

In some example embodiments, the comparator cluster 1111 may perform the comparison operation by referring to the plurality of reference pattern data stored in the pattern register 1116. The memory controller 1100 may transmit and/or send the training pattern data stored in the pattern register 1116 to the memory device 1200.

The final delay amount may be stored in the delay register 1117. In some example embodiments, the training control circuit 1115 may store final delay information indicating the final delay amount for the data signal DQ in the delay register 1117. Alternatively, in some example embodiments, the training control circuit 1115 may store determined timing compensation information in the delay register 1117. The timing compensation information may indicate the degree of timing compensation of the data signal DQ and/or the degree of timing compensation of the data strobe signal DQS. For example, the delay register 1117 may store the final delay amount determined in the write training operation, or a final delay amount determined in the read training operation. After the training operation is completed, the memory controller 1100 may perform the input/output operation with reference to the stored final delay information.

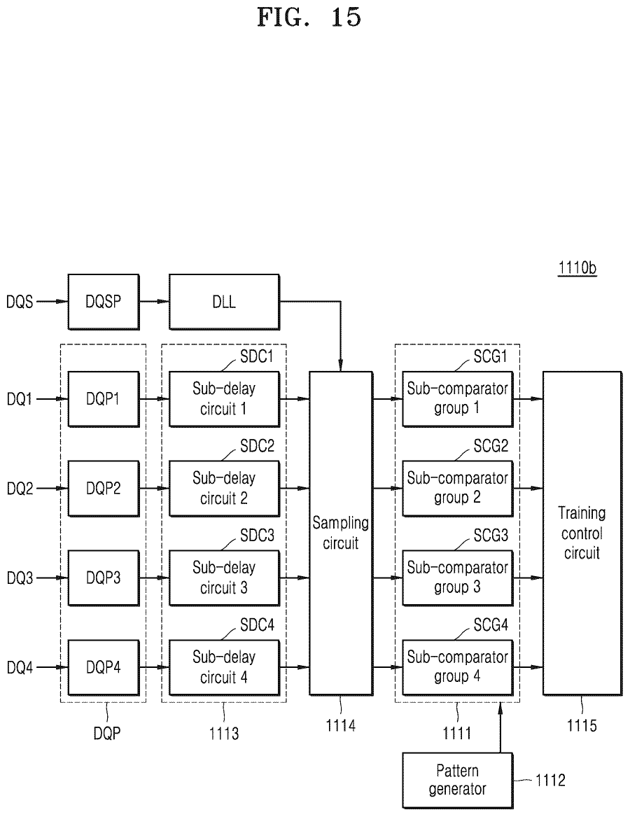

FIG. 15 is a more detailed block diagram of the training circuit 1110 in FIG. 1 according to some example embodiments.

Although a data signal is expressed as the data signal DQ in FIGS. 1 through 14, it will be understood by one of ordinary skill in the art that this may include a plurality of data signals rather than a single signal. According to some example embodiments, the parallel training operation on the plurality of data signals is described in more detail with reference to FIG. 15.

A training circuit 1110b may be configured to perform the training operation. The training circuit 1110b may adjust, to the center, the sampling time point of each of the first through fourth data signals DQ1 through DQ4 provided by the memory device 1200 by performing the training. For example, to adjust the sampling time point of the first through fourth data signals DQ1 through DQ4 to the center, an operation of detecting the center of each of the first through fourth data signals DQ1 through DQ4 may be performed in advance in the training circuit 1110.

The training circuit 1110b may include a plurality of data input/output pads DQPs, a data strobe pad DQSP, a delay lock loop DLL, the comparator cluster 1111, the pattern generator 1112, the delay circuit 1113, the sampling circuit 1114, and the training control circuit 1115. Although FIG. 15 illustrates that the plurality of data input/output pads DQPs, the data strobe pad DQSP, and the delay lock loop DLL are included in the training circuit 1110b, example embodiments are not limited thereto. In some example embodiments, the plurality of data input/output pads DQPs, the data strobe pad DQSP, and the delay lock loop DLL may be configured outside the training circuit 1110b.

The data strobe pad DQSP may receive the data strobe signal DQS from the memory device 1200. However, example embodiments are not limited thereto, and, in some example embodiments, the data strobe pad DQSP may output the data strobe signal DQS to the memory device 1200, and components for outputting the data strobe signal DQS may be provided in the memory controller 1100. The data strobe pad DQSP may transmit and/or send the received data strobe signal DQS to the delay lock loop DLL.

The plurality of data input/output pads DQPs may receive the first through fourth data signals DQ1 through DQ4 from the memory device 1200. However, example embodiments are not limited thereto, and, in some example embodiments, the data input/output pads DQPs may output the first through fourth data signals DQ1 through DQ4 to the memory device 1200, and components for outputting the first through fourth data signals DQ1 through DQ4 may be provided in the memory controller 1100. The plurality of data input/output pads DQPs may transmit and/or send pattern data received via the first through fourth data signals DQ1 through DQ4 to the delay circuit 1113. The first through fourth data signals DQ1 through DQ4 may have different delays for each data signal due to noise or a difference in delay characteristics. Accordingly, alignment between the data strobe signal DQS and the first through fourth data signals DQ1 through DQ4 may be advantageous to perform during the training.

The delay circuit 1113 may receive the pattern data (for example, a plurality of bit data) from the plurality of data input/output pads DQPs. The delay circuit 1113 may receive the delay control signal from the training control circuit 1115. For example, the delay control signal may indicate the delay code. The delay circuit 1113 may delay and output the received pattern data in response to the delay control signal.

For example, each of the delay circuits 1113 may include the plurality of delay cells for adjusting the timing of the data signal corresponding to each of the delay circuits 1113. The delay circuit 1113 may individually control the timing (or delay amounts) of sampling each of the first through fourth data signals DQ1 through DQ4 by activating the plurality of delay cells, in response to the delay control signal. The delay circuit 1113 may provide delayed first through fourth data signals DQ1 through DQ4 to the sampling circuit 1114.

The plurality of data input/output pads DQPs may include first through fourth data input/output pads DQP1 through DQP4. The delay circuit 1113 may include first through fourth sub-delay circuits SDC1 through SDC4. The plurality of data signals DQ may include first through fourth data signals DQ1 through DQ4. A plurality of delay control signals may include first through fourth input delay control signals.

The first through fourth sub-delay circuits SDC1 through SDC4 may be connected to the first through fourth data input/output pads DQP1 through DQP4, respectively. For example, the first sub-delay circuit SDC1 may be connected to the first data input/output pad DQP1, the second sub-delay circuit SDC2 may be connected to the second data input/output pad DQP2, the third sub-delay circuit SDC3 may be connected to the third data input/output pad DQP3, and the fourth sub-delay circuit SDC4 may be connected to the fourth data input/output pad DQP4.

Each of the first through fourth sub-delay circuits SDC1 through SDC4 may receive an input delay control signal corresponding thereto. Each of the first through fourth sub-delay circuits SDC1 through SDC4 may individually control timings (for example, delay amounts) of the data signals, in response to the input delay control signal corresponding thereto. For example, the first sub-delay circuit SDC1 may adjust the timing (e.g., delay amount) of transmitting and/or sending the first data signal DQ1, in response to a first input delay control signal. Similarly, the remaining second through fourth sub-delay circuits SDC2 through SDC4 may receive second through fourth input delay control signals corresponding thereto, respectively, adjust the timings of the data signals in response thereto, and thus a detailed description thereof is omitted.

The sampling circuit 1114 may receive a clock or a delayed data strobe signal from the delay lock loop DLL. The sampling circuit 1114 may receive the first through fourth data signals DQ1 through DQ4 from the delay circuit 1113. The sampling circuit 1114 may store the delay pattern data received via the first through fourth data signals DQ1 through DQ4 as the sampling data and output the sampling data. The sampling circuit 1114 may provide the sampling data to the comparator cluster 1111.

The comparator cluster 1111 may include first through fourth sub-comparator groups SCG1 through SCG4. In some example embodiments, each of the first through fourth sub-comparator groups SCG1 through SCG4 may include the plurality of comparators. For example, each of the plurality of comparators included in the first sub-comparator group SCG1 may compare the reference pattern data to first sub-sampling data corresponding thereto. The first sub-sampling data may indicate the sampling data generated based on pattern data received via the first data signal DQ1. The first sub-comparator group SCG1 may simultaneously compare the plurality of reference pattern data to the first sub-sampling data, and generate the comparison result. The first sub-comparator group SCG1 may provide the comparison result corresponding to the first data signal DQ1 to the training control circuit 1115.

The training control circuit 1115 may receive the comparison result from the comparator cluster 1111. The training control circuit 1115 may detect the FP comparator and the PF comparator of each of the first through fourth data signals DQ1 through DQ4, based on the comparison result, and detect the center of each of the first through fourth data signals DQ1 through DQ4, based on the detected FP comparator and PF comparator. In other words, the training control circuit 1115 may detect the left edge LE and the right edge RE of each of the first through fourth data signals DQ1 through DQ4, and may detect the center of each of the first through fourth data signals DQ1 through DQ4 based on the detected left edge LE and right edge RE.

The training control circuit 1115 may output a clock control signal and transmit and/or send the clock control signal to the delay lock loop DLL. The training control circuit 1115 may output the delay control signal and transmit and/or send the delay control signal to the delay circuit 1113.

The training control circuit 1115 may control the delay lock loop DLL by using the clock control signal. The training control circuit 1115 may control the clock control signal, and adjust the delay amount of the data strobe signal DQS.

In some example embodiments, the training control circuit 1115 may repeatedly perform the sub-training operation while shifting each of the first through fourth data signals DQ1 through DQ4 by the delay step (or tick time). The training control circuit 1115 may repeat the sub-training operation while shifting each of the first through fourth data signals DQ1 through DQ4 by the delay step (or tick time) with respect to the ‘1 UI’.

For example, the delay step (or tick time) may be a minimum unit or a smallest unit of the delay amount of the data strobe signal DQS or the data signal DQ shifted or delayed by the training circuit 1110. Alternatively, in some example embodiments, the delay step (or tick time) may be the minimum unit or smallest unit at which the data strobe signal DQS or the data signal DQ is shifted by the training circuit 1110.

The training control circuit 1115 may detect the FP comparator and the PF comparator of each of the first through fourth data signals DQ1 through DQ4. Alternatively, in some example embodiments, the training control circuit 1115 may detect the reference pattern data in the FP state and the reference pattern data in the PF state. As a result, the training control circuit 1115 may detect the left edge LE and the right edge RE of each of the first through fourth data signals DQ1 through DQ4.

The training control circuit 1115 may adjust the timing or delay amount of each of the first through fourth data signals DQ1 through DQ4 by using the delay control signal. The training control circuit 1115 may detect the center of the window of each of the first through fourth data signals DQ1 through DQ4 based on the FP comparator and the PF comparator of each of the detected first through fourth data signals DQ1 through DQ4. The training control circuit 1115 may align the data signals DQ or align the data strobe signals DQS, based on the FP comparator and PF comparator of each of the detected first through fourth data signals DQ1 through DQ4. The training control circuit 1115 may generate the delay control signal based on the FP comparator and the PF comparator (or, left edge LE offset and right edge RE offset).

The delay lock loop DLL may receive the data strobe signal DQS from the data strobe pad DQSP. The delay lock loop DLL may receive the clock control signal from the training control circuit 1115. The delay lock loop DLL may delay and output the data strobe signal DQS based on the clock control signal. The delay lock loop DLL may provide the delayed data strobe signal DQS to the sampling circuit 1114. For example, the delay lock loop DLL may include the plurality of delay cells for controlling the timing of the data strobe signal DQS. The delay lock loop DLL may adjust the timing of the data strobe signal DQS, by activating the plurality of delay cells under the control of the clock control signal. However, example embodiments are not limited thereto, and, in some example embodiments, the memory controller 1100 may include a phase-locked loop PLL instead of a delay lock loop DLL.

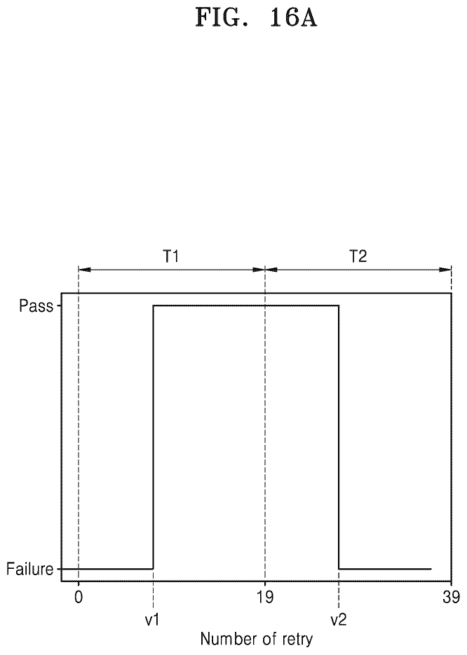

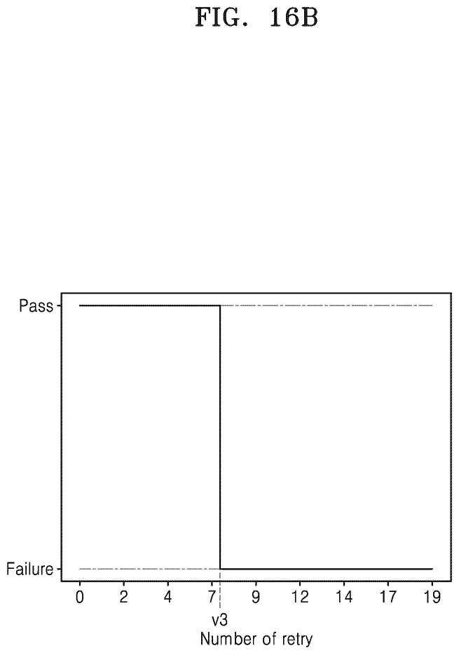

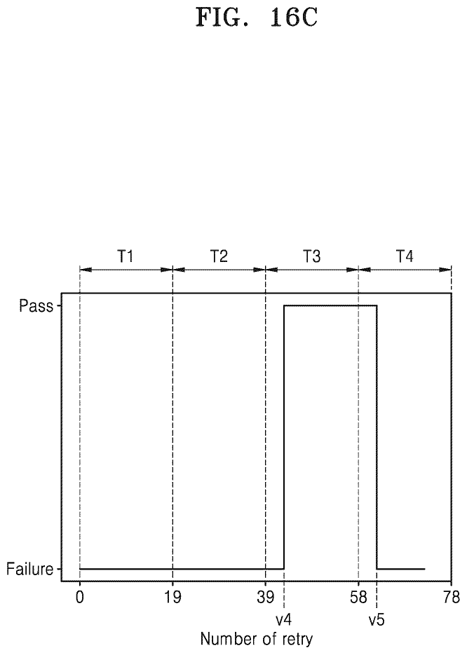

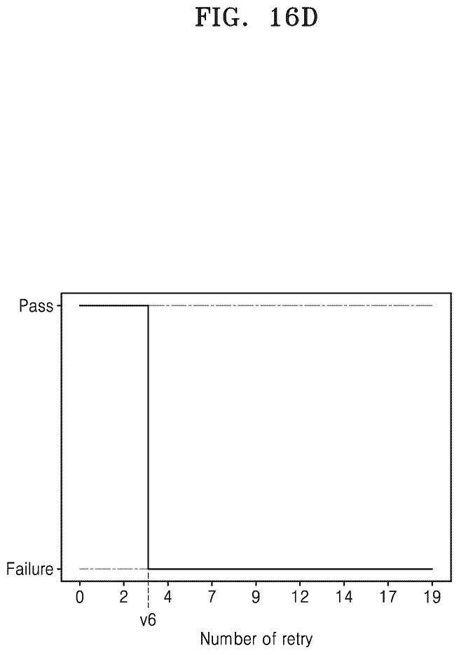

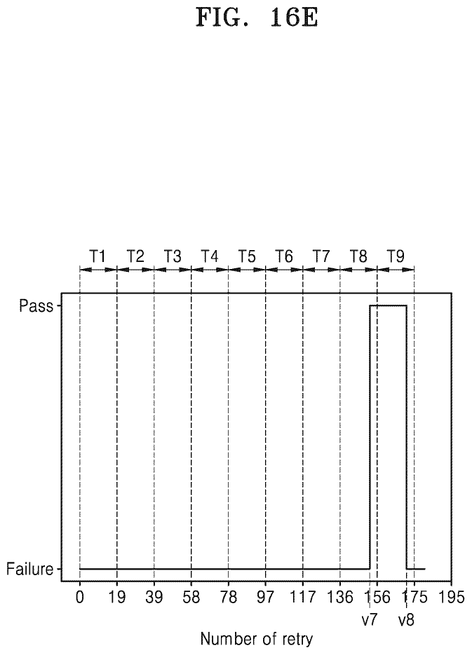

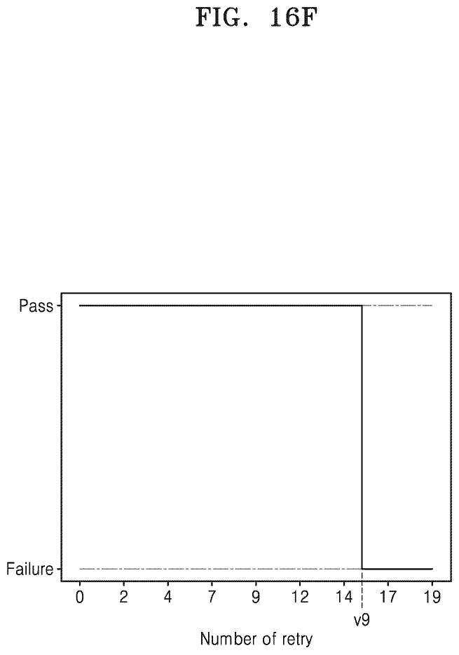

FIG. 16A through FIG. 16F are graphs of effects of a memory system, according to some example embodiments.

FIGS. 16A, 16C, and 16E illustrate results of general training operations according to some example embodiments, and FIGS. 16B, 16D, and 16F illustrate results of parallel training operations according to some example embodiments. Referring to FIGS. 16A through 16F, the horizontal axis may indicate the total number of sub-training operations (or the number of retries), and the vertical axis may indicate the comparison result. For example, the comparison result may indicate whether the reference pattern data is the same as the sampling data.

In some example embodiments, it is assumed that the initial delay amounts in FIGS. 16A and 16B are about −0.9 UI, those in FIGS. 16C and 16D are about −2.7 UI, and those in FIGS. 16E and 16F are about −8.3 UI. Referring to FIGS. 16A, 16C, and 16E, it is assumed that each of first through ninth intervals T1 through T9 indicates 1UI. Referring to FIGS. 16B, 16D, and 16F, a solid line indicates the reference pattern data in the PF state, and a dash-dot line indicates the reference pattern data in the FP state.

Referring to FIG. 16A, when the number of sub-training operations is less than a first step number v1, the comparison result may be the second value (for example, Fail). When the number of sub-training operations is the first step number v1 (e.g., equal to the first step number v1), the comparison result may transition from the second value (for example, Fail) to the first value (for example, Pass). When the number of sub-training operations is greater than the first step number v1 and less than a second step number v2, the comparison result may be the first value (for example, Pass). When the number of sub-training operations is the second step number v2 (e.g., equal to the second step number v2), the comparison result may transition from the first value (for example, Pass) to the second value (for example, Fail). When the number of sub-training operations is greater than the second step number v2, the comparison result may indicate the second value (for example, Fail).

A training circuit may repeatedly perform a sub-training operation while changing a delay code (or increasing a delay amount) until a left edge and a right edge are detected. For example, when the initial delay amount is about −0.9 UI, the training circuit may repeat the sub-training operation about 25 times. The training circuit may detect the left edge LE in a first interval T1 and the right edge RE in a second section T2. For example, the training circuit may detect the center of the window, by increasing the delay amount to a maximum or total of 2 UI.

Referring to FIG. 16B, when the number of sub-training operations is less than a third step number v3, the comparison result of the reference pattern data having the PF state may include the first value (for example, Pass), and the comparison result of the reference pattern data having the FP state may include the second value (for example, Fail). When the number of sub-training operations is the third step number v3, the comparison result of reference pattern data having the PF state may transition from the first value (for example, Pass) to the second value (for example, Fail), and the comparison result of reference pattern data having the FP state may transition from the second value (for example, Fail) to the first value (for example, Pass). When the number of sub-training operations is greater than the third step number v3, the comparison result of the reference pattern data having the PF state may include the second value (for example, Fail), and the comparison result of the reference pattern data having the FP state may include the first value (for example, Pass).

The training circuit 1110 may repeatedly perform the sub-training operation while changing the delay code (or increasing the delay amount), until the reference pattern data having the FP state and the reference pattern data having the PF state are detected. For example, when the initial delay amount is about −0.9 UI, the training circuit 1110 may repeat the sub-training operation about 8 times. For example, the training circuit 1110 may detect the center of the window, by increasing the delay amount to a maximum or total of 1 UI.

Referring to FIG. 16C, when the number of sub-training operations is less than a fourth step number v4, the comparison result may be the second value (for example, Fail). When the number of sub-training operations is the fourth step number v4 (e.g., equal to the fourth step number v4), the comparison result may transition from the second value (for example, Fail) to the first value (for example, Pass). When the number of sub-training operations is greater than the fourth step number v4 and less than a fifth step number v5, the comparison result may be the first value (for example, Pass). When the number of sub-training operations is the fifth step number v5 (e.g., equal to the fifth step number v5), the comparison result may transition from the first value (for example, Pass) to the second value (for example, Fail). When the number of sub-training operations is greater than the fifth step number v5, the comparison result may indicate the second value (for example, Fail).

For example, when the initial delay amount is about −2.7 UI, the training circuit may repeat the sub-training operation about 60 times. The training circuit may detect the left edge LE in a third interval T3, and the right edge RE in a fourth section T4. For example, the training circuit may detect the center of the window, by increasing the delay amount to a maximum or total of 4 UI.

Referring to FIG. 16D, when the number of sub-training operations is less than a sixth step number v6, the comparison result of the reference pattern data having the PF state may include the first value (for example, Pass), and the comparison result of the reference pattern data having the FP state may include the second value (for example, Fail). When the number of sub-training operations is the sixth step number v6, the comparison result of reference pattern data having the PF state may transition from the first value (for example, Pass) to the second value (for example, Fail), and the comparison result of reference pattern data having the FP state may transition from the second value (for example, Fail) to the first value (for example, Pass). When the number of sub-training operations is greater than the sixth step number v6, the comparison result of the reference pattern data having the PF state may include the second value (for example, Fail), and the comparison result of the reference pattern data having the FP state may include the first value (for example, Pass).

For example, when the initial delay amount is about −2.7 UI, the training circuit 1110 may repeat the sub-training operation about 4 times. For example, the training circuit 1110 may detect the center of the window, by increasing the delay amount to a maximum or total of 1 UI.

Referring to FIG. 16E, when the number of sub-training operations is less than a seventh step number v7, the comparison result may be the second value (for example, Fail). When the number of sub-training operations is the seventh step number v7 (e.g., equal to the seventh step number v7), the comparison result may transition from the second value (for example, Fail) to the first value (for example, Pass). When the number of sub-training operations is greater than the seventh step number v7 and less than an eighth step number v8, the comparison result may be the first value (for example, Pass). When the number of sub-training operations is the eighth step number v8 (e.g., equal to the eight step number v8), the comparison result may transition from the first value (for example, Pass) to the second value (for example, Fail). When the number of sub-training operations is greater than the eighth step number v8, the comparison result may indicate the second value (for example, Fail).

For example, when the initial delay amount is about −8.3 UI, the training circuit may repeat the sub-training operation about 170 times. The training circuit may detect the left edge LE in an eighth interval T8, and the right edge RE in a ninth section T9. For example, the training circuit may detect the center of the window, by increasing the delay amount to a maximum or total of 9 UI.

Referring to FIG. 16F, when the number of sub-training operations is less than the ninth step number v9, the comparison result of the reference pattern data having the PF state may include the first value (for example, Pass), and the comparison result of the reference pattern data having the FP state may include the second value (for example, Fail). When the number of sub-training operations is the ninth step number v9 (e.g., equal to the ninth step number v9), the comparison result of reference pattern data having the PF state may transition from the first value (for example, Pass) to the second value (for example, Fail), and the comparison result of reference pattern data having the FP state may transition from the second value (for example, Fail) to the first value (for example, Pass). When the number of sub-training operations is greater than the ninth step number v9, the comparison result of the reference pattern data having the PF state may include the second value (for example, Fail), and the comparison result of the reference pattern data having the FP state may include the first value (for example, Pass).

For example, when the initial delay amount is about −8.3 UI, the training circuit 1110 may repeat the sub-training operation about 15 times. For example, the training circuit 1110 may detect the center of the window, by increasing the delay amount to a maximum or total of 1 UI.

As described above, as the initial delay amount increases, the number of sub-training operations performed in a general training circuit may rapidly increase. However, the training circuit 1110 according to some example embodiments may detect the center of the window, by increasing the delay amount of the data signal DQ by up to 1 UI. Accordingly, the training execution time may be reduced and the training speed may be improved.

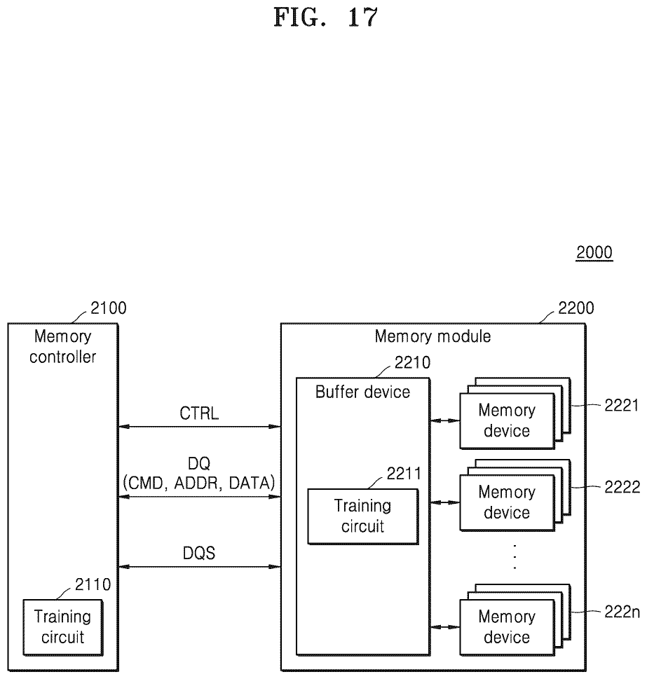

FIG. 17 is a block diagram illustrating a memory system 2000 according to some example embodiments.

Referring to FIG. 17, the memory system 2000 may include a memory controller 2100 and a memory module 2200. The memory module 2200 may include a buffer device 2210 (or a buffer chip) and a plurality of memory devices 2221 through 222n (or memory chips). For example, each of a plurality of memory devices 2221 through 222n may be implemented as a separate chip or a separate package. The buffer device 2210 may be connected between the memory controller 2100 and the plurality of memory devices 2221 through 222n.

The memory controller 2100 may control a memory operation on the plurality of memory devices 2221 through 222n. The memory controller 2100 may transmit and/or send the control signal CTRL, the data signal DQ, and the data strobe signal DQS. The buffer device 2210 may receive the address ADDR, the command CMD, and the data DATA. The buffer device 2210 may route the address ADDR, the command CMD, and the data DATA to the plurality of memory devices 2221 through 222n. The buffer device 2210 may transmit and/or send the address ADDR, the command CMD, and the data DATA to a memory device corresponding to the address ADDR or the control signal CTRL.

The plurality of memory devices 2221 through 222n may receive the address ADDR, the command CMD, and the data DATA from the buffer device 2210, and perform a memory operation (or an input/output operation) including a write operation and a read operation, based on the received address ADDR, command CMD, and data DATA.

The plurality of memory devices 2221 through 222n may include a memory cell array (not illustrated), and the memory cell array may include a plurality of memory cells arranged in regions where a plurality of word lines and a plurality of bit lines cross each other.

In some example embodiments, the plurality of memory cells included in each of the plurality of memory devices 2221 through 222n may include volatile memory cells or nonvolatile memory cells. For example, the plurality of memory cells may include non-volatile memory cells, such as a flash memory, resistive random access memory (RAM) (RRAM), phase change RAM (PRAM), and MRAM, and/or moreover, volatile memory cells such as DRAM.

The memory controller 2100 may include a training circuit 2110. The training circuit 2110 may generate the plurality of reference pattern data. The training circuit 2110 may control parallel training operations of the buffer device 2210. The training circuit 2110 may perform the parallel training operations of the buffer device 2210. The memory controller 2100 may determine the delay amount (or a degree of delay) for a signal transmitted and/or sent to the buffer device 2210 and the delay amount for a signal received from the buffer device 2210. The buffer device 2210 may include a training circuit 2211. The training circuit 2211 may generate the plurality of reference pattern data. The training circuit 2211 may control the parallel training operations on the plurality of memory devices 2221 through 222n. The training circuit 2211 may perform the parallel training operations on the plurality of memory devices 2221 through 222n. The memory controller 2100 may determine the delay amount (or a degree of delay) for a signal transmitted and/or sent to each of the plurality of memory devices 2221 through 222n and a delay amount for a signal received from each of the plurality of memory devices 2221 through 222n.

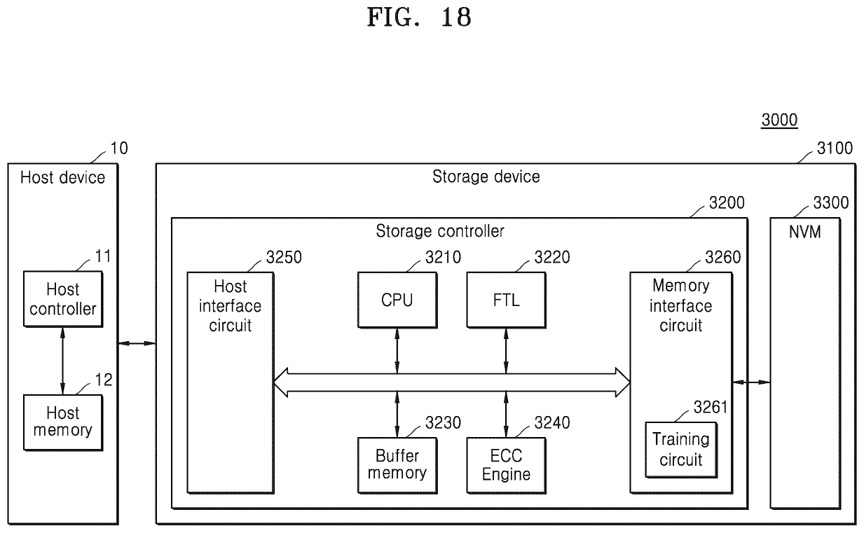

FIG. 18 is a block diagram of a storage system 3000 according to some example embodiments.

Referring to FIG. 18, the storage system 3000 may include a host device 10 and a storage device 3100. The host device 10 may control a data processing operation, for example, a data read operation, a data write operation, and/or the like on the storage device 3100. The host device 10 may be referred to as a data processing device capable of processing data, such as a CPU, a processor, a microprocessor, and/or an application processor (AP). The host device 10 may perform an operating system (OS) and/or various applications.

The host device 10 may include a host controller 11 and a host memory 12. The host controller 11 may include a device configured to control the overall operation of the host device 10 and/or to control the storage device 3100 from the side of the host device 10. The host memory 12 may include a buffer memory, a cache memory, and/or an operation memory, which are used by the host device 10. The host memory 12 may load various software and/or data driven by the host device 10.

The storage device 3100 may operate under the control of the host device 10. The storage device 3100 may include a storage controller 3200 and a non-volatile memory device 3300. The storage controller 3200 may manage the non-volatile memory device 3300. The storage controller 3200 may perform various management operations for efficiently using the non-volatile memory device 3300. The non-volatile memory device 3300 may include a plurality of non-volatile memories.

When the non-volatile memory device 3300 includes a flash memory, the flash memory may include a two-dimensional (2D) NAND array and/or a three-dimensional (3D) (or vertical) NAND memory array. In some example embodiments, the storage device 3100 may also include various other types of non-volatile memories. For example, the storage device 3100 may include MRAM, spin-transfer torque MRAM, conductive bridging RAM (CBRAM), ferroelectric RAM (FeRAM), phase RAM (PRAM), RRAM, and/or other various types of memories.

The storage controller 3200 may include a CPU 3210, a flash transformation layer (FTL) 3220, a buffer memory 3230, an error correction code (ECC) engine 3240, a host interface circuit 3250, and a non-volatile memory interface circuit 3260. The storage controller 3200 may further include a working memory (not illustrated) in which the FTL 3220 is loaded, and the data write operation and the data read operation on the non-volatile memory device 3300 may be controlled by the CPU 3210 by executing the flash translation layer.

In some example embodiments, the CPU 3210 may be implemented as a multi core processor, for example, a dual core processor and/or a quad core processor. The FTL 3220 may be loaded into an operation memory of the storage controller 3200. For example, the operation memory may be implemented as a volatile memory, such as SRAM and DRAM, or as a non-volatile memory, such as a flash memory and PRAM.

The FTL 3220 may perform various functions, such as address mapping, wear-leveling, and garbage collection. The address mapping operation may include an operation of converting a logical address received from the host device 10 into a physical address used to actually store data in the non-volatile memory device 3300. The wear-leveling operation may be a technology for preventing and/or reducing excessive deterioration of a particular or alternatively, a desired block by uniformly using blocks in the non-volatile memory device 3300, and may be implemented by using firmware technology that balances erase counts of physical blocks. The garbage collection operation may be a technology for securing usable capacity in the non-volatile memory device 3300 by copying the effective data of a block to a new block and then erasing the block.

The buffer memory 3230 may be configured to temporarily store write data received from the host device 10 and/or data read from the non-volatile memory device 3300 under the control of the storage controller 3200. Hereinafter, it is assumed that the buffer memory 3230 includes SRAM. However, example embodiments are not limited thereto.

The ECC engine 3240 may perform an error detection operation and correction function on read data read from the non-volatile memory device 3300. The ECC engine 3240 may generate parity bits for write data to be written in the non-volatile memory device 3300, and the generated parity bits may be stored in the non-volatile memory device 3300 together with the write data. When data is read from the non-volatile memory device 3300, the ECC engine 3240 may correct an error in read data by using parity bits read from the non-volatile memory device 3300 together with read data, and output error-corrected read data.

The host interface circuit 3250 may transceive packets to and from the host device 10. The packet transmitted and/or sent from the host device 10 to the host interface circuit 3250 may include a command, a request RQ, and/or data to be recorded in the non-volatile memory device 3300, and the packet transmitted and/or sent from the host interface circuit 3250 to the host device 10 may include a response to the command and/or data read from the non-volatile memory device 3300.

The non-volatile memory interface circuit 3260 may transmit and/or send data to be recorded in the non-volatile memory device 3300 to the non-volatile memory device 3300, or receive data read from the non-volatile memory device 3300. The non-volatile memory interface circuit 3260 may be implemented to comply with standard conventions, such as a Toggle and/or an open NAND flash interface (ONFI).

In some example embodiments, the non-volatile memory interface circuit 3260 may include a training circuit 3261. Based on the method described according to some example embodiments with reference to FIGS. 1 through 17, the training circuit 3261 may perform the parallel training operation on the non-volatile memory device 3300. The training circuit 3261 may simultaneously compare the plurality of reference pattern data to the sampling data by using the plurality of comparators. The training circuit 3261 may simultaneously train the delay in units of delay steps and the delay in units of intervals. Accordingly, the training time may be reduced and the training speed may be improved.

According to some example embodiments, a memory system may generate a plurality of reference pattern data in which basic pattern data is cyclically shifted in units of intervals, and may generate a comparison result by comparing sampling data and the plurality of reference pattern data in parallel. The memory system may determine a final delay amount of a data signal based on a comparison result. Accordingly, a memory system having an improved training speed, a memory controller, and/or a method of operating the memory controller is provided.

Some example embodiments provide a method of operating a memory system including a memory device and a memory controller configured to control the memory device, the method of operating the memory system comprising: generating, by the memory controller, a plurality of reference pattern data by cyclically shifting basic pattern data by units of unit intervals; generating, by the memory controller, a comparison result by simultaneously comparing sampling data to the plurality of reference pattern data by performing, repeatedly, a sub-training operation; and calculating, by the memory controller, a center of a window of a data signal based on the comparison result.

In some example embodiments, the sub-training operation includes, receiving, by the memory controller, pattern data from the memory device via the data signal; generating, by the memory controller, delay pattern data by delaying the pattern data based on a delay code; generating, by the memory controller, the sampling data by sampling the delay pattern data based on a clock signal generated based on a data strobe signal received from the memory device; and generating, by the memory controller, the comparison result by comparing simultaneously the sampling data to the plurality of reference pattern data.

In some example embodiments, the comparison result indicates a first value in response to the sampling data being identical to a corresponding reference pattern data of the plurality of reference pattern data, and the comparison result indicates a second value in response to the sampling data not being identical to the corresponding reference pattern data of the plurality of reference pattern data.

In some example embodiments, the method of operating the memory system further includes: detecting, by the memory controller, a pass-fail (PF) comparator that includes a comparison result value that is changed from the first value to the second value, based on the comparison result; and detecting, by the memory controller, a fail-pass (FP) comparator that includes a comparison result value that is changed from the second value to the first value, based on the comparison result.

In addition, some example embodiments provide a non-transitory computer readable medium comprising instructions, that when executed by a memory system including a memory device and a memory controller configured to control the memory device, cause the memory system to perform at least generating a plurality of reference pattern data by cyclically shifting basic pattern data by units of unit intervals, generating a comparison result by simultaneously comparing sampling data to the plurality of reference pattern data by performing, repeatedly, a sub-training operation, and calculating a center of a window of a data signal based on the comparison result.

It will be understood that elements and/or properties thereof recited herein as being “the same” or “equal” as other elements, and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are identical or substantially identical to and/or the same or substantially the same as other elements and/or properties thereof may be structurally the same or substantially the same, functionally the same or substantially the same, and/or compositionally the same or substantially the same.

As described herein, any devices, electronic devices, modules, units, and/or portions thereof according to any of the example embodiments, and/or any portions thereof may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, electronic devices, modules, units, and/or portions thereof according to any of the example embodiments.

Further, any or all of the elements described with reference to the figures may communicate with any or all other elements described with reference to the figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be encoded in various formats, such as in an analog format and/or in a digital format.

The above descriptions are some example embodiments for implementing the inventive concepts. The inventive concepts will include the example embodiments described above, as well as example embodiments in which the design is simply changed and/or easily changeable. In addition, the inventive concepts will include techniques that may be easily modified and implemented by using the example embodiments. Therefore, the scope of the inventive concepts should not be construed as being limited to the above-described example embodiments, and may be defined by equivalents to the claims of the inventive concepts as well as the following claims.

What is claimed is:

1. A memory system, comprising:
a memory device; and
a memory controller configured to control the memory device, the memory controller including a training circuit, the training circuit configured to,
generate a plurality of reference pattern data, the plurality of reference pattern data including a plurality of pieces of reference pattern data, the plurality of pieces of reference pattern data generated by cyclically shifting basic pattern data in units of unit intervals;
generate a comparison result by simultaneously comparing the plurality of reference pattern data to sampling data; and
calculate a center of a window of a data signal based on the comparison result.

2. The memory system of claim 1, wherein
the training circuit includes,
a pattern generator configured to generate the plurality of reference pattern data based on the basic pattern data; and
a comparator cluster including a plurality of comparators, and
each of the plurality of comparators is configured to,
receive the sampling data;
receive corresponding reference pattern data from the pattern generator;
compare the sampling data to the corresponding reference pattern data; and
generate the comparison result.

3. The memory system of claim 2, wherein
the training circuit further comprises,
a delay circuit configured to receive a delay code from a training control circuit, receive pattern data via a data signal from the memory device, and delay the pattern data based on the delay code;
a sampling circuit configured to receive delay pattern data output by the delay circuit, receive a clock signal, and generate the sampling data by sampling the delay pattern data based on the clock signal; and
the training control circuit configured to generate the delay code, receive the comparison result from the comparator cluster, and calculate the center of the window of the data signal based on the comparison result, and
the clock signal is generated based on a data strobe signal received from the memory device.

4. The memory system of claim 3, wherein the basic pattern data comprises bit data corresponding to a basic pattern and bit data corresponding to an auxiliary pattern.

5. The memory system of claim 3, wherein the training control circuit is configured to deactivate a comparator that is not used among the plurality of comparators, by using a comparator control signal.

6. The memory system of claim 3, wherein
the comparison result indicates a first value in response to the sampling data being identical to the corresponding reference pattern data, and
the comparison result indicates a second value in response to the sampling data not being identical to the corresponding reference pattern data.

7. The memory system of claim 6, wherein
the training control circuit is configured to detect, based on the comparison result, a pass-fail (PF) comparator from among the plurality of comparators that includes a comparison result value that is changed from the first value to the second value, and a fail-pass (FP) comparator from among the plurality of comparators that includes a comparison result value that is changed from the second value to the first value.

8. The memory system of claim 7, wherein
the training control circuit is configured to determine a final delay amount of the data signal, based on a first initial delay amount corresponding to the PF comparator and a second initial delay amount corresponding to the FP comparator.

9. The memory system of claim 8, wherein the training circuit further comprises a delay register configured to store the final delay amount.

10. The memory system of claim 3, wherein
the training circuit further comprises a pattern register configured to store at least one of the basic pattern data, the plurality of reference pattern data, and training pattern data.

11. The memory system of claim 3, wherein
the training circuit is configured to repeatedly perform a sub-training operation while increasing the delay code up to 1 unit interval (UI), and
the sub-training operation indicates an operation of receiving the pattern data, comparing simultaneously the sampling data to the plurality of reference pattern data, and generating the comparison result.

12. The memory system of claim 1, wherein
the memory controller is configured to determine any one of the plurality of reference pattern data as training pattern data, and send the training pattern data to the memory device.

13. The memory system of claim 12, wherein
the memory device is configured to receive the training pattern data, and send a signal generated by sampling the training pattern data to the memory controller as the pattern data.

14. The memory system of claim 12, wherein the training pattern data comprises data in which the basic pattern data is cyclically shifted by a maximum unit interval.

15. A method of operating a memory controller, the method comprising:
generating a plurality of reference pattern data by cyclically shifting basic pattern data by units of unit intervals;
generating a comparison result by simultaneously comparing sampling data to the plurality of reference pattern data by performing, repeatedly, a sub-training operation; and
calculating a center of a window of a data signal based on the comparison result.

16. The method of claim 15, wherein the sub-training operation includes,
receiving pattern data from an external memory device via the data signal;
generating delay pattern data by delaying the pattern data based on a delay code;
generating the sampling data by sampling the delay pattern data, based on a clock signal generated based on a data strobe signal received from the external memory device; and
generating the comparison result by comparing simultaneously the sampling data to the plurality of reference pattern data.

17. The method of claim 15, wherein
the comparison result indicates a first value in response to the sampling data being identical to a corresponding reference pattern data of the plurality of reference pattern data, and
the comparison result indicates a second value in response to the sampling data not being identical to the corresponding reference pattern data of the plurality of reference pattern data.

18. The method of claim 17, further comprising:
detecting a pass-fail (PF) comparator that includes a comparison result value that is changed from the first value to the second value, based on the comparison result; and
detecting a fail-pass (FP) comparator that includes a comparison result value that is changed from the second value to the first value, based on the comparison result.

19. The method of claim 18, further comprising:
determining a final delay amount of the data signal, based on a first initial delay amount corresponding to the PF comparator and a second initial delay amount corresponding to the FP comparator.

20. A memory controller configured to control a memory device, the memory controller comprising:
a training circuit, the training circuit including,
a pattern generator configured to generate a plurality of reference pattern data by cyclically shifting basic pattern data by units of unit intervals; and
a comparator cluster including a plurality of comparators, each of the plurality of comparators configured to receive sampling data, receive corresponding reference pattern data from the pattern generator, compare the sampling data to the corresponding reference pattern data, and generate a comparison result.
